(19) United States
(12) Patent Application Publication
(10) Pub. No.: US 2026/0083014 A1
(43) Pub. Date: Mar. 19, 2026

(54) THREE-DIMENSIONAL DEVICE PACKAGING FANOUT

(71) Applicant: Applied Materials, Inc., Santa Clara, CA (US)

(72) Inventors: Guan-Shian CHEN, Sunnyvale, CA (US); Yi ZHENG, Sunnyvale, CA (US); Sohrab KIANIAN, Los Altos hills, CA (US); Kuma HSIUNG, Hsinchu (TW)

(21) Appl. No.: 19/330,472

(22) Filed: Sep. 16, 2025

Related U.S. Application Data
(60) Provisional application No. 63/696,332, filed on Sep. 18, 2024.

(51) Int. Cl. H10W 90/00; H10W 70/05; H10W 70/09; H10W 70/60; H10W 90/22

(52) U.S. Cl. CPC H10W 90/00; H10W 70/09; H10W 70/093; H10W 70/60; H10W 90/22; H10W 90/724

(57) ABSTRACT

Embodiments of the disclosure include a method of forming a device package, comprising: forming a device containing layer over a supporting surface of a first substrate, wherein forming the device containing layer comprises: forming a plurality of first openings in a first dielectric layer that is formed over a first conductive layer, wherein the first conductive layer has a first thickness, and is formed over a first bonding layer positioned between the supporting surface and the device containing layer, and a first portion of the first conductive layer is exposed within each of a plurality of first openings formed in the first dielectric layer; forming a second conductive layer on the first portions of the first conductive layer to form a pillar in each of the first openings, wherein the pillars have a second thickness; removing the first dielectric layer, wherein a second portion of the first conductive layer is exposed after removing the first dielectric layer, and the second portion of the first conductive layer is disposed over a first portion of the first substrate; removing the second portion of the first conductive layer; positioning one or more electronic devices over the first portion of the first substrate and adjacent to a pillar, wherein the one or more electronic devices have a device thickness that is less than or equal to the second thickness of the pillar; depositing a molding material over the pillars and the one or more electronic devices; and forming, by use of a material removal process, a planar surface that comprises a portion of the molding material, a portion of the one or more electronic devices, and a portion of the pillars.

### CROSS-REFERENCE TO RELATED APPLICATIONS

This application claims the benefit of U.S. provisional patent application Ser. No. 63/696,332, filed Sep. 18, 2024, which is herein incorporated by reference.

### BACKGROUND

### Field

Embodiments of the present disclosure generally relate to apparatus, systems, and methods of forming three-dimensional (3D) device containing packages.

### Description of the Related Art

Electronic devices, such as tablets, computers, copiers, digital cameras, smart phones, control systems, and automated teller machines, among others, often include integrated circuit die(s) for some desired functionality. A heterogeneous integration module (HIM) (which may also be referred to or be a type of multi-chip module (MCM)) is a type of microelectronics device that integrates multiple different chips, electrical components, and/or technologies into a single compact package. This approach allows designers to create more complex and powerful systems by integrating different components, without the need for full system-on-chip integration. For example, this type of device aims to provide a high level of functionality and performance while also reducing the overall size, cost, and complexity of the system. HIMs devices are commonly used in a wide range of applications, including smartphones, wearable devices, and internet of things (IoT) devices, as well as in various fields such as telecommunications, computing, and robotics. They are designed to overcome the limitations of traditional microelectronics devices, which often rely on a single technology or material, by bringing together complementary components and technologies in a single, integrated package. Some examples of HIMS devices include multi-layer microelectronics packages, system-in-package (SiP) devices, and 2D and 3D integrated circuits (ICs). These devices can offer improved performance, higher functional density, and better thermal management compared to traditional microelectronics devices. However, combining different components into a single component package, if they are not oriented and structured properly, can lead to device performance issues.

In general, 3D packaging refers to three-dimensional (3D) integration schemes that rely on various interconnection methods such as wire bonding and flip chip technologies to achieve vertical stacking of devices. Three-dimensional (3D) packaging structures can include stacked memory dies interconnected with wire bonds and package-on-package (PoP) configurations interconnected with wire bonds or flip chip technology. Conventional device interconnection schemes within package-on-package (PoP) configurations are complex, require the use of solder ball containing interfaces, and require large lateral distances between interconnected components, which can affect device performance.

Accordingly, there is a need in the art for an improved apparatus, systems, and methods of forming three-dimensional (3D) device-containing packages.

### SUMMARY

Embodiments of the disclosure include a method of forming a device package, comprising: forming a device containing layer over a supporting surface of a first substrate, wherein forming the device containing layer comprises: forming a plurality of first openings in a first dielectric layer that is formed over a first conductive layer, wherein the first conductive layer has a first thickness, and is formed over a first bonding layer positioned between the supporting surface and the device containing layer, and a first portion of the first conductive layer is exposed within each of a plurality of first openings formed in the first dielectric layer; forming a second conductive layer on the first portions of the first conductive layer to form a pillar in each of the first openings, wherein the pillars have a second thickness; removing the first dielectric layer, wherein a second portion of the first conductive layer is exposed after removing the first dielectric layer, and the second portion of the first conductive layer is disposed over a first portion of the first substrate; removing the second portion of the first conductive layer; positioning one or more electronic devices over the first portion of the first substrate and adjacent to a pillar, wherein the one or more electronic devices have a device thickness that is less than or equal to the second thickness of the pillar; depositing a molding material over the pillars and the one or more electronic devices; and forming, by use of a material removal process, a planar surface that comprises a portion of the molding material, a portion of the one or more electronic devices, and a portion of the pillars.

In one or more of the embodiments disclosed herein, a method of forming a device package comprises: forming a plurality of first openings in a dielectric layer that is formed over a first conductive layer, wherein the first conductive layer has a first thickness, the first conductive layer is formed over a surface of a device containing layer that is disposed over a surface of a first substrate, the first conductive layer is formed over a portion of one or more electronic devices and a portion of one or more first pillars disposed within the device containing layer, and the one or more first pillars comprise a second conductive layer, and a first portion of the first conductive layer is exposed within each of a plurality of first openings formed in the dielectric layer; forming a third conductive layer on the first portions of the first conductive layer within each of the plurality of first openings to form a second pillar in each of the first openings, wherein the second pillars have a second thickness; removing the dielectric layer, wherein a second portion of the first conductive layer is exposed after removing the dielectric layer, and the second portion of the first conductive layer is disposed over a first portion of the device containing layer; removing the second portion of the first conductive layer; positioning one or more electronic devices over the first portion of the first substrate and adjacent to a second pillar, wherein the one or more electronic devices have a device thickness that is less than or equal to the second thickness of the second pillar; depositing a molding material over the second pillars and the one or more electronic devices; and forming, by use of a material removal process, a planar surface that comprises a portion of the molding material, a portion of the one or more electronic devices, and a portion of the second pillars.

In one or more of the embodiments disclosed herein, a method of forming a device package comprises: bonding a first device layer structure to a second device layer structure, wherein bonding the first device layer structure to the second device layer structure comprises: bonding conductive regions within an interconnect layer of the first device layer structure to conductive regions within an interconnect layer of the second device layer structure, wherein the first device layer structure is positioned over a first substrate, and the first device layer structure comprises: the interconnect layer, which comprises the conductive regions that are coupled to a plurality of traces, a plurality of pillars that are coupled to the plurality of traces, and a plurality of first electronic devices that comprise device contacts that are coupled to the plurality of traces and the pillars, and the second device layer structure is positioned over a second substrate, and the second device layer structure comprises: the interconnect layer, which comprises the conductive regions that are coupled to a plurality of traces, a plurality of pillars that are coupled to the plurality of traces, and a plurality of second electronic devices that comprise device contacts that are coupled to the plurality of traces and the pillars; separating the second substrate from the second device layer structure, wherein separating the second substrate from the second device layer structure exposes a surface of the second device layer structure; and bonding a third device layer structure to the surface of the second device layer structure, wherein bonding the third device layer structure to the second device layer structure comprises: bonding conductive regions within an interconnect layer of the third device layer structure to conductive regions within the interconnect layer of the second device layer structure, wherein the third device layer structure is positioned over a third substrate, and the third device layer structure comprises: the interconnect layer, which comprises the conductive regions that are coupled to a plurality of traces, a plurality of pillars that are coupled to the plurality of traces, and a plurality of third electronic devices that comprise device contacts that are coupled to the plurality of traces and the pillars.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of their scope, and may admit to other equally effective embodiments.

FIG. 1A is a schematic view of a portion of a three-dimensional (3D) device package, according to one or more embodiments.

FIG. 1B is a schematic view of a portion of a three-dimensional (3D) device package that is integrated into and/or configured to communicate with components of an external electronic device, according to one or more embodiments.

FIG. 2 is a cross-sectional view of a device containing layer for use within a three-dimensional (3D) device package, according to one or more embodiments.

FIG. 3 is a process flow diagram of a method of forming a device containing layer within a three-dimensional (3D) device package, according to one or more embodiments.

FIGS. 4A-4K are cross-sectional views of the device containing layer within the three-dimensional (3D) device package during different stages of the method illustrated in FIG. 3, according to one or more embodiments.

FIG. 5 is a cross-sectional view of a device containing layer that includes an interconnect layer formed thereon, according to one or more embodiments.

FIG. 6 is a process flow diagram of a method of forming one or more redistribution layers within an interconnect layer that is formed over the first device containing layer, according to one or more embodiments.

FIGS. 7A-7E are cross-sectional views of different stages of the formation of a first redistribution layer within an interconnect layer of a device layer structure during the performance of the method illustrated in FIG. 6, according to one or more embodiments.

FIGS. 7F-7J are cross-sectional views of different stages of the formation of a second redistribution layer within the interconnect layer of the device layer structure by performing the method illustrated in FIG. 6 a second time, according to one or more embodiments.

FIG. 7K is a cross-sectional view of a device layer structure after the formation of a third redistribution layer within the interconnect layer of the device layer structure of FIG. 5, according to one or more embodiments.

FIG. 8 is a cross-sectional view of two device containing layers formed within a device layer structure, according to one or more embodiments.

FIG. 9 is a process flow diagram of a method of forming a second device containing layer and interconnect layer over a first device containing layer within a device layer structure, according to one or more embodiments.

FIGS. 10A-10J are cross-sectional views of the device containing layer within the three-dimensional (3D) device package during different stages of the method illustrated in FIG. 9, according to one or more embodiments.

FIG. 10K is a cross-sectional view of a device layer structure after the formation of the redistribution layers within an interconnect layer within the device layer structure, according to one or more embodiments.

FIG. 10L is a cross-sectional view of a device layer structure after the formation of a third device containing layer and an interconnect layer of a device layer structure, according to one or more embodiments.

FIG. 11 is a cross-sectional view of three device containing layers formed within a device layer structure, according to one or more embodiments.

FIG. 12 is a process flow diagram of a method of interconnecting contacts formed on a backside surface of an electronic device formed within a device layer structure, according to one or more embodiments.

FIGS. 13A-13D are cross-sectional views of device containing layers within the three-dimensional (3D) device package during different stages of the method illustrated in FIG. 12, according to one or more embodiments.

FIG. 14 is a process flow diagram of a method of forming a device layer structure using formed device containing layers, according to one or more embodiments.

FIGS. 15A-15D are cross-sectional views of device containing layers within the three-dimensional (3D) device package during different stages of the method illustrated in FIG. 14, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

One or more embodiments disclosed herein include a method of forming a three-dimensional (3D) device package, such as a package-on-package (PoP) device package. The package-on-package (PoP) device structure disclosed herein generally includes active and passive electronic devices formed in a vertically stacked configuration to reduce interconnect line lengths and improve the delivery of power (i.e., low interconnect line loss) between internal and external devices. The vertically stacked configuration disclosed herein is used to achieve a device package that has a more compact form factor that enables a reduction in power loss and provides an improved device processing speed (e.g., RC time constant) between the interconnected device, which is especially useful in forming or working in combination with devices used to form a graphic processing unit (GPU) and/or other useful power delivery applications that can be used with various types of electronic devices, such as mobile devices and consumer electronics.

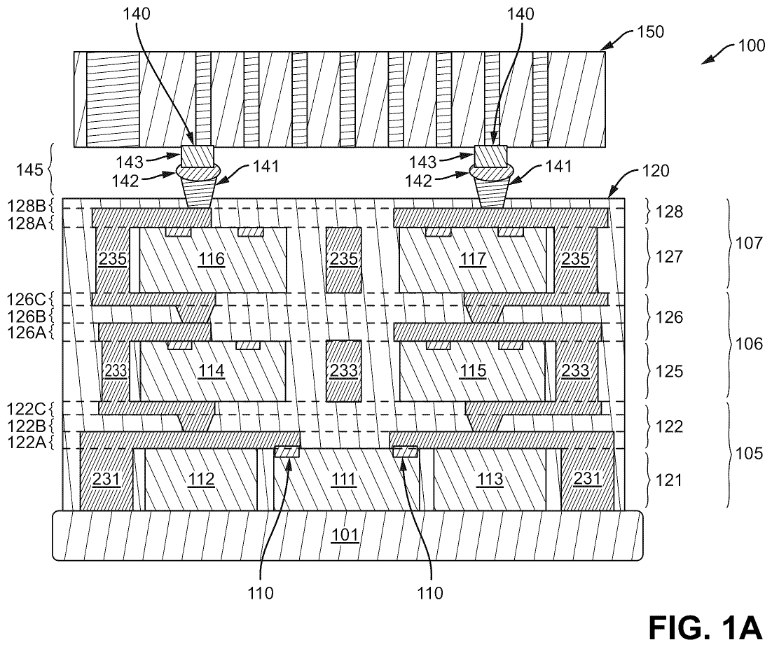

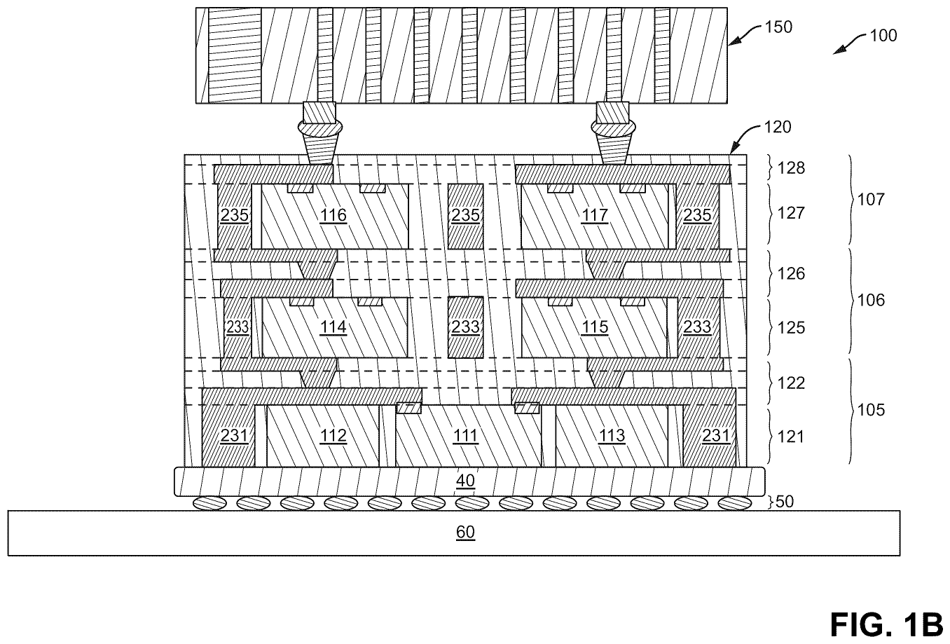

FIG. 1A is a schematic view of a portion of a three-dimensional (3D) device package, which is referred to herein as a device package 100. The device package 100 illustrated in FIG. 1A is an example of one of many types of three-dimensional (3D) device packages that can benefit from one or more aspects of the device structures and methods of forming the same that are disclosed herein. The device package 100 illustrated in FIG. 1A is a side cross-sectional view of a portion of the three-dimensional (3D) device package during an interim manufacturing stage before being integrated into a three-dimensional (3D) device package structure, such as a package-on-package (PoP) device structure.

FIG. 1B is a schematic view of the device package 100 that is integrated into and/or configured to communicate with components within an external electronic device. In some embodiments, as shown in FIG. 1B, the device package 100 is source mounted on a printed circuit board (PCB) 40 that includes a plurality of traces that are configured to facilitate the communication with elements of a ball-grid-array (BGA) connection region 50 of the PCB 40 to facilitate the communication with a motherboard 60 of an electronic device, such as a mobile phone, personal digital assistant (PDA), and digital camera, laptops, gaming devices, or other useful electronic device. However, in some other embodiments, rather than being source-mounted, the device package 100 can be embedded within a portion of the PCB 40. In one example, as will be discussed further below, the electronic devices 111-117 within the device package 100 are in communication with the plurality of traces formed in the PCB 40, and thus the mother board 60, by use of the interconnecting elements (e.g, pillars 231-235 and interconnect layers 122, 126, and 128) formed with the device package 100.

The device package 100 includes a device layer stack 120 mounted on a carrier substrate 101 and coupled to one or more electrical components 150. The device layer stack 120 includes a plurality of device layer structures, such as a first device layer structure 105, a second device layer structure 106, and a third device layer structure 107. While FIG. 1A illustrates a device package 100 that includes three device layer structures, a device package 100 can include two or more device layer structures. Each of the device layer structures will include a device containing layer and one or more interconnection layers. In one example, as shown in FIG. 1A, the device package 100 includes device containing layers 121, 125, and 127, and interconnect layers 122, 126, and 128. The interconnect layers can include one or more redistribution layers, such as redistribution layers 122A-122C, 126A-126C, and 128A-128B, disposed within the interconnect layers 122, 126, and 128.

The device containing layers 121, 125, and 127 within the device layer stack 120 includes one or more electronic devices (e.g., dies or chiplets), a pillar structure, and one or more interconnecting vias (not shown) that extend through the device containing layer. In general, each of the device containing layers within the device layer stack 120 can include a plurality of electronic devices. In the example shown in FIG. 1A, the first device containing layer 121 includes three electronic devices 111, 112, and 113, and two pillars 231, which are described in greater detail below. In one example, the electronic device 111 can include a control die that includes a plurality of contacts 110 formed therein, and the electronic devices 112, 113 each include a dummy device. At least one of the three electronic devices 111, 112, and 113 within the first device containing layer 121 is interconnected to one or more of the other electrical components disposed within the device containing layers 125, 127 by use of the redistribution layers 122A-122C formed within the interconnect layer 122.

As illustrated in the cross-sectional view shown in FIG. 1A, a second device containing layer 125 includes two electronic devices 114 and 115, and pillars 233. The electronic devices 114, 115 can each include a die, a chiplet, a passive component (e.g., capacitor), or a dummy device. In one example, the electronic devices 114, 115 include two passive components, such as two capacitors. At least one of the two electronic devices 114, 115 within the second device containing layer 125 is interconnected to one or more of the other electrical components disposed within the device containing layers 121, 127 by use of the redistribution layers 126A-126C formed within the interconnect layer 126.

The third device containing layer 127 includes two electronic devices 116 and 117, and pillars 235. The electronic devices 116, 117 can each include a die, a chiplet, a passive component (e.g., capacitor), or a dummy device. In one example, the electronic devices 116, 117 include two dies or chiplets, such as a first metal-oxide-semiconductor-field-effect-transistor (MOSFET) and a second MOSFET, which can include a low-frequency MOSFET and a high-frequency MOSFET, respectively. In some embodiments, one or more of the electronic devices, such as electronic devices 116, 117 can be a MOSFET (high side and low side switch), integrated half-bridge IC (high side+low side+gate driver). In some configurations, the number of the devices can be more than two as in the case of multiple parallel phases DCDC converter or other circuit topology. The devices can also be GaN transistors and GaN IC, which are used as high frequency switching devices. At least one of the two electronic devices 116, 117 within the third device containing layer 127 is interconnected to one or more of the other electrical components disposed within the device containing layers 121, 125 by use of the redistribution layers 128A-128B formed within the interconnect layer 128.

Still referring to FIG. 1A, the device layer stack 120 can be coupled to one or more electrical components 150, such as an inductor, by use of interconnects 140 that can each include a contact 141, solder ball 142, and contact 143 that are disposed within an interconnect region 145. The contact 141 is coupled to, or forms part of, conductive regions formed within at least one of the redistribution layers 128A-128B within the interconnect layer 128, and the contact 143 can form part of an electrical component 150.

As illustrated in FIG. 1A, each of the device containing layers 121, 125, 127 includes a plurality of pillars that are formed within the vertically oriented device layer stack 120 structure. Each of the plurality of pillars has a circular, square, or rectangular-shaped lateral cross-section or includes a trench-like structure that has a lateral length dimension that is significantly larger than its vertical height. As will be discussed further below, in some embodiments, a plurality of pillars can be formed in a circular or rectangular array of discrete pillars that form a region or boundary around one or more of the electronic devices positioned within a device containing layer, such as the device containing layers 121, 125, 127. In one aspect of the disclosure provided herein, the device containing layer structures include pillars that enable the interconnection of the vertically stacked electronic devices, which is more compact and enables a reduction in power loss and provides an improved device processing speed performance between the interconnected devices.

### Device Containing Layer Formation Process Example

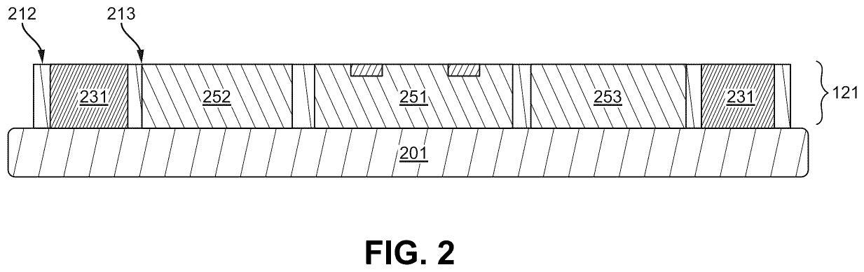

FIG. 2 is a side cross-sectional view of a first device containing layer 121 that is disposed over the surface of a carrier substrate 201. The first device containing layer 121 includes three electronic devices 251, 252, and 253, and pillars 231. The three electronic devices 251, 252, and 253 can be similarly configured as the three electronic devices 111, 112, and 113 shown in FIG. 1A, which can include one or more integrated circuit (IC) devices (e.g., dies or chiplets) and/or dummy devices.

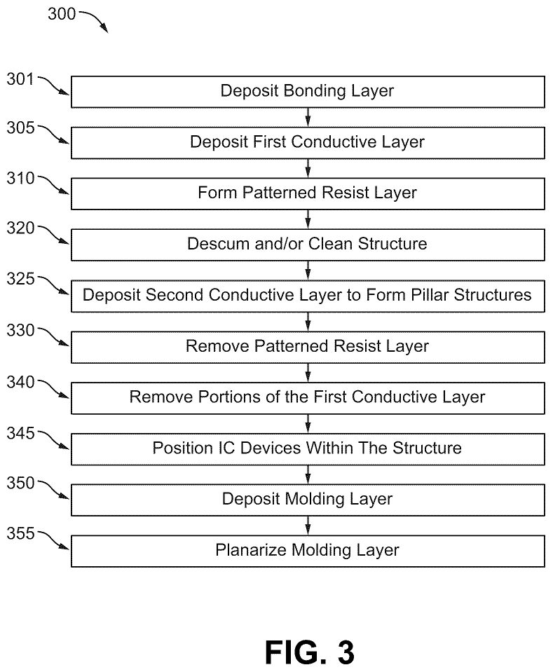

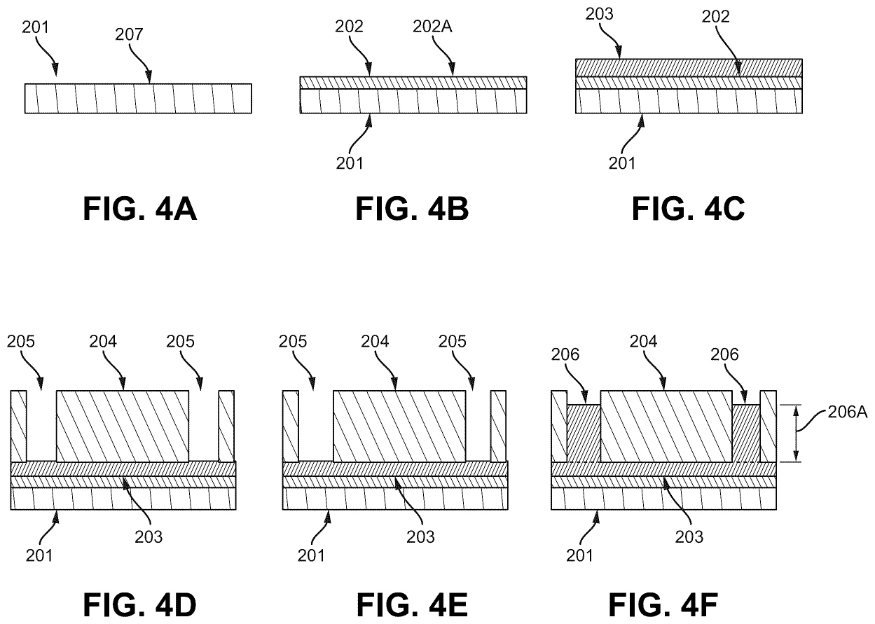

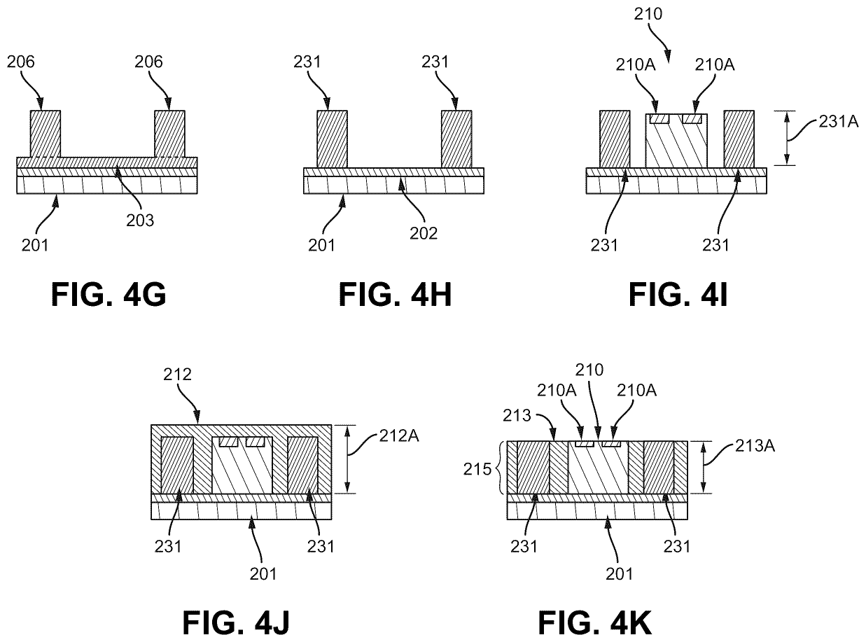

FIG. 3 depicts an example of a device containing layer formation process, often referred to as method 300, which can be used to form a device containing layer (FIG. 2) within a first portion of a device layer stack 120 of a device package 100. FIGS. 4A-4K are cross-sectional views of the device containing layer 121 within the three-dimensional (3D) device package during different stages of the performance of method 300.

At operation 301, a surface 207 of the substrate 201 (FIG. 4A) is positioned on a surface of a substrate support that is disposed within a deposition chamber, and a bonding layer 202 (FIG. 4B) is deposited on the surface 207 of the substrate 201. The substrate 201 can include a glass sheet, a silicon substrate, a metal substrate, or a ceramic substrate. The substrate 201 may have various dimensions, such as 200 mm, 300 mm, 450 mm, or other diameter wafers, as well as, rectangular or square panels. The bonding layers 202 will include a material layer adapted to adhere to and/or form a bond with the surface 207 of the substrate 201. The bonding layer 202 includes a material or materials selected to allow the exposed upper surface 202A of the deposited material layer(s) to form a detachable bonding layer while covering the underlying topography and surface variation found on the surface 207. In one example, the bonding layers 202 include a polymeric material, such as an epoxy material, acrylic, polyimide, cyanate esters, or UV curable materials, that can be deposited on the surface 207 by use of a spin-coating process, printing process, or doctor-blade deposition process. In some embodiments, the bonding layer 202 can include a thermoplastic material that is deposited and transformed to include a desired planar exterior surface shape by use of a thermal processing step. In one example, a bonding layer deposition chamber within a multi-chamber processing tool is configured to perform a slit coating process, a spray coating process, a molding process, a lamination process, a spin-coating process, or a doctor-blade deposition process to deposit an epoxy-containing layer on the surface 207 of the substrate 201.

At operation 305, as shown in FIG. 4C, a first conductive layer 203 is formed over the bonding layers 202 by use of one or more material deposition processes. The one or more material deposition processes can include a physical vapor deposition (PVD) process, chemical vapor deposition (CVD) process, plasma enhanced CVD (PECVD) process, atomic layer deposition (ALD) process, plasma enhanced ALD (PEALD) process, an electroless deposition process, or other useful conductive layer deposition process. In some embodiments, the first conductive layer 203 includes one or more metals that are selected from a group that includes copper (Cu), titanium (Ti), tantalum (Ta), aluminum (Al), cobalt (Co), ruthenium (Ru), molybdenum (Mo), silver (Ag), gold (Au), tungsten (W), and nickel (Ni) and can have a thickness of about 0.5 micrometer (μm) to about 10 μm, such as about 1 μm to about 7 μm. In one example, the first conductive layer 203 is a seed layer that includes copper (Cu) that has a thickness of about 5 μm and is deposited over the bonding layers 202 by use of a PVD process. The first conductive layer 203 deposition process can be performed within a first metal deposition chamber within the multi-chamber processing tool.

At operation 310, as shown in FIG. 4D, a patterned resist layer formation process is performed over the formed first conductive layer 203. The patterning process will include exposing portions of a resist layer 204 to electromagnetic radiation, such as coherent radiation emitted from a laser source. In some embodiments, the processes performed during operation 310 are configured to generate the radiation-exposed portions of the resist layer 204 that can be selectively removed versus unexposed regions of the resist layer 204 during subsequent processing steps performed during operation 310. In one example, the resist layer 204 includes a photosensitive resist material and the patterning process comprises scanning an IR or UV laser over sections of the resist layer 204 positioned within a photolithography patterning chamber within a multi-chamber processing tool to form the radiation-exposed portions that can then be selectively removed in a develop chamber within the multi-chamber processing tool to form openings 205 within the resist layer 204. Laser power, pulse duration, wavelength, and scanning speed are all used to control the type and extent of microstructural changes in the exposed resist layer 204. The develop processes can include exposing portions of the resist layer 204 to a wet develop process and/or dry develop process to selectively remove the radiation-exposed portions of the resist layer 204 to form the openings 205.

At operation 320, as shown in FIG. 4E, one or more descum or cleaning processes are performed, which are used to remove contamination found on the patterned surfaces of the patterned resist layer 204. The descum or cleaning processes can include wet and/or dry cleaning processes. In one example, a wet clean chamber is configured to perform a wet clean process to clean the surfaces of the patterned resist layer 204, and exposed portions of the first conductive layer 203 exposed within the openings 205 via delivery of a fluid, such as water, a cleaning chemistry, or both, while the substrate 201 is rotated at desired revolutions-per-minute (RPM). The cleaning chemistry can include an acid, base, or solvent-containing solution configured to at least remove an oxide or organic material disposed on the exposed portions of the first conductive layer 203 exposed within the openings 205.

At operation 325, as shown in FIG. 4F, a second conductive layer 206 is formed within the openings 205 formed in the resist layer 204 by use of one or more material deposition processes. As will be discussed further below, the deposited second conductive layer 206 forms pillars 231 (FIG. 2) within the first device containing layer 121. The one or more material deposition processes can include a physical vapor deposition (PVD) process, an electroplating process, an electroless deposition process, or other useful conductive layer deposition processes. In some embodiments, the second conductive layer 206 includes one or more metals that are selected from a group that includes copper (Cu), titanium (Ti), tantalum (Ta), aluminum (Al), cobalt (Co), ruthenium (Ru), molybdenum (Mo), silver (Ag), gold (Au), tungsten (W), and nickel (Ni). In one example, the second conductive layer 206 includes a copper layer that is deposited within the openings 205 by use of an electroplating process. The thickness of the deposited second conductive layer 206 is selected such that the thickness is at least as thick as a die or chiplet (e.g., electronic device 251, 252, or 253) that is to be positioned within the device containing layers 121 in a subsequent operation. In some examples, the formed pillars can have a thickness 206A of about 25 μm to about 100 μm, such as about 40 μm to about 80 μm. In one example, the conductive layer 206 includes a copper layer that has a thickness of about 50 μm and is deposited over the exposed portion of conductive layer 203 within the openings 205 by use of an electroplating process. The conductive layer 206 deposition process can be performed within a second metal deposition chamber within the multi-chamber processing tool.

At operation 330, as shown in FIG. 4G, the patterned resist layer 204 is removed to expose a portion of the first conductive layer 203 and the second conductive layer 206. The patterned resist layer removal processes can include exposing portions of the resist layer 204 to a conventional resist removal process, which can include a wet etching process (e.g., solvent containing fluid) and/or dry etching process (e.g., oxygen plasma). The patterned resist layer removal process can be performed within a processing chamber within the multi-chamber processing tool.

At operation 340, as shown in FIG. 4H, exposed portions of the first conductive layer 203 are removed from the surface of the bonding layer 202 to form the pillars 231. The material removal processes can include exposing portions of the first conductive layer 203 and second conductive layer 206 to a wet etching process and/or dry etching process to remove the exposed portions of the first conductive layer 203 disposed between the second conductive layer 206 containing regions formed over the bonding layer 202, and form the pillars 231. The pillars 231 form structural features and portions of interconnects, which are coupled to one or more electronic devices within the device containing layer 121. In some embodiments of operation 340, the process of removing the first conductive layer 203 is not selectively relative to the material formed within the second conductive layer 206 and thus the thickness 206A of the deposited second conductive layer 206 is selected, during operation 325, to assure that the height 231A (FIG. 4I) of the formed pillars 231 is at least as large as the thickness of the die or chiplet (e.g., electronic device 251, 252, or 253) that is to be positioned within the device containing layers 121 during operation 345. The first conductive layer material removal process can be performed within a processing chamber within the multi-chamber processing tool.

Next, at operation 345, one or more electronic devices are positioned over a portion of the substrate 201 and bonding layer 202 and between and/or adjacent to a pillar 231 formed within a pillar containing structure formed over the bonding layer surface 202A and substrate surface 201A. In one example, as shown in FIG. 4I, an electronic device 210 is positioned between two adjacent pillars 231. As discussed above, an electronic device that can be positioned during operation 345 can include positioning a die or chiplet, passive device, or dummy device. The thickness of the electronic device will typically be equal to or less than the height 231A of the formed pillar 231, which is created during the performance of operations 305-340.

At operation 350, a molding layer is deposited over the surface of the substrate 201, which includes the pillars 231, bonding layer 202, and electronic device 210, as shown in FIG. 4J. The molding process will include the deposition of molding material 212 by use of, for example, a spin-coating process, printing process or docter-blade deposition process. In one example, the molding material 212 includes a dielectric material, such as an oxide material (e.g., silicon dioxide) or polymeric material, such as an epoxy material, acrylic, polyimide, cyanate esters, or UV curable materials, that can be deposited over the substrate. In some embodiments, the molding material 212 can include a thermoplastic material. In one example, a molding material deposition chamber is disposed within a multi-chamber processing tool that is configured to perform a slit coating process, a spray coating process, a molding process, a spin-coating process, or a doctor-blade deposition process to deposit an epoxy-containing layer over the surface of the substrate. In some embodiments of operation 350, the thickness 212A of the deposited molding layer is selected to assure that the thickness 212A of the molded layer is at least as large as the thickness of the die or chiplet (e.g., electronic device 251, 252, or 253).

Next, at operation 355, as shown in FIG. 4K, the molding material layer, pillars 231, and upper surface of the electronic devices are planarized by use of one or more material removal processes to form a substantially planar surface 213. Due to the rigidity and planar surface characteristics (e.g., surface topography) of the first substrate 201, the process of planarizing the surface of the substrate allows the planar surface 213 to include minimal topography or surface variation. In some embodiments of operation 355, the one or more material removal processes include a grinding and/or polishing process, such as a chemical mechanical polishing (CMP) process. In one example, operation 355 includes a CMP process that is configured to form the planar surface 213 that has a peak-to-peak flatness between about 1 micrometers (μm) and 100 (μm). In one example, the one or more material removal processes are configured to remove portions of the pillars 231 and contacts 210A of the electronic device 210 by use of a CMP process to form the planar surface 213. Therefore, the processes performed during operation 355 are performed to significantly reduce the thickness variation across the thickness of the substrate 201 and expose portions of the contacts 210A of the electronic device 210. The processes performed during operation 355 can be used to improve the yield of the die-to-substrate bonding process due to the high degree of flatness or coplanarity of the surfaces in the formed package, and also provide improved warpage control. In some embodiments of operation 355, the thickness 213A of the first device containing layer 121, after performing operation 355, is selected to assure that portions of the pillars 231 and contacts 210A of the electronic device 210 (e.g., electronic device 251, 252, or 253) are exposed.

### Interconnect Layer Formation Process Examples

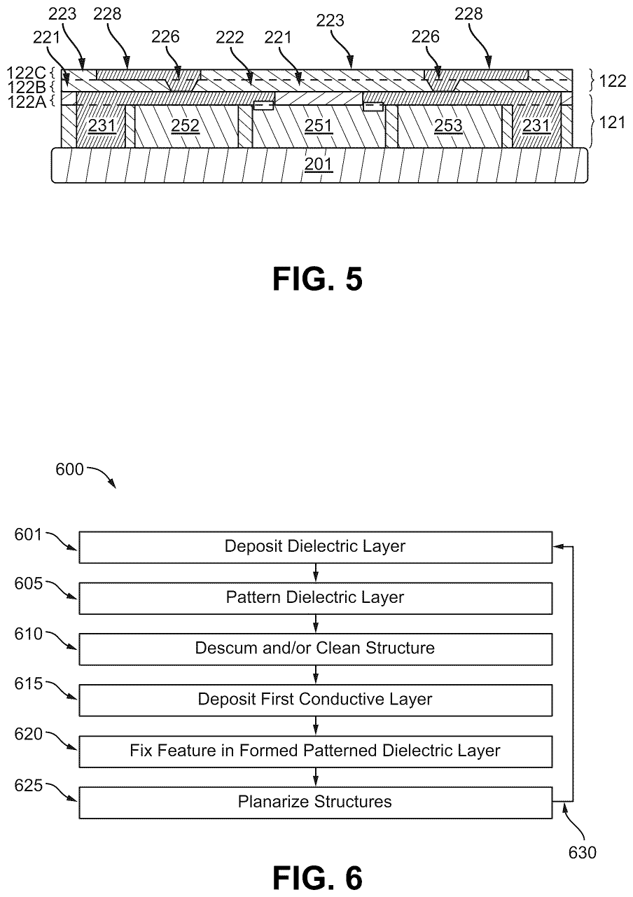

FIG. 5 is a side cross-sectional view of the first device containing layer 121 that includes an interconnect layer, such as interconnect layer 122 positioned thereover. The interconnect layer 122 includes three redistribution layers 122A-122C that are coupled one or more interconnecting features formed in the first device containing layer 121. The one or more interconnecting features will include the contacts 210A of the electronic device 210 and the pillars 231, for example. The redistribution layers 122A, 122B, 122C include a plurality of interconnecting traces 222, 226, 228 formed within dielectric layers 221, 223, 225, respectively, in each level of the interconnect layer 122.

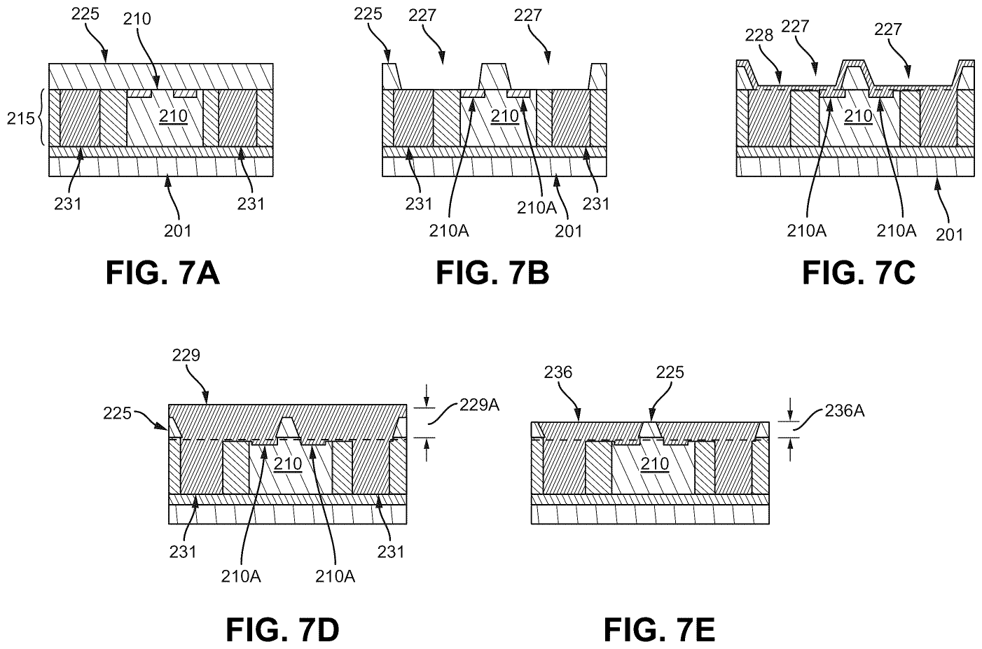

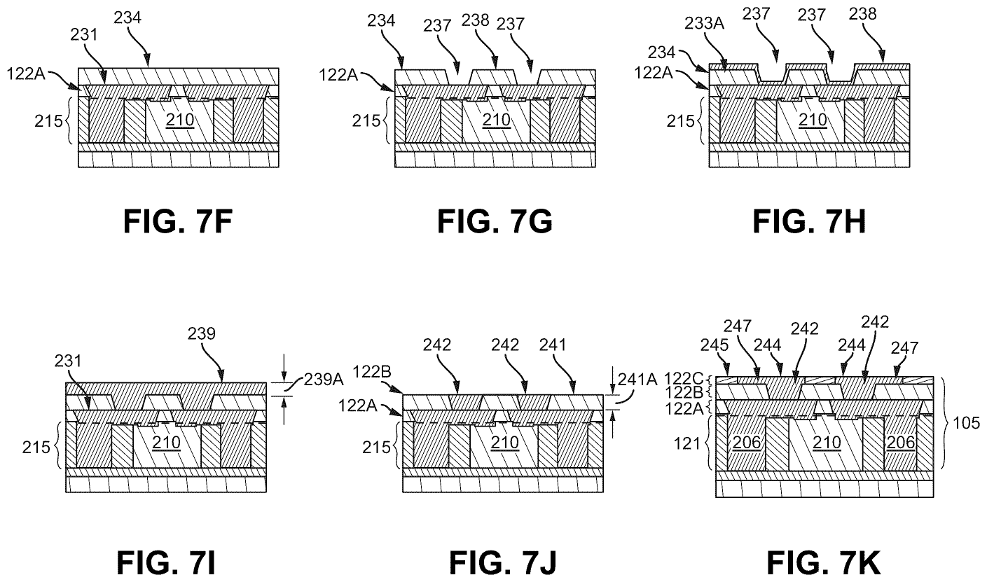

FIG. 6 depicts an example of an interconnect layer formation process, or method 600, which can be used to form one or more of the redistribution layers 122A-122C (FIG. 5) within a device layer stack 120 of a device package 100. FIGS. 7A-7J are cross-sectional views of portions of a first redistribution layer 122A that is being formed by use of the operations of method 600 over the previously formed device containing layer 121.

At operation 601, a dielectric layer 225 is deposited over the surface of the first device containing layer 121, which includes the pillars 231 and electronic device 210, as shown in FIG. 7A. The dielectric layer deposition process will include the deposition of dielectric layer 225 by use of, for example, a spin-coating process, printing process, or doctor-blade deposition process. In one example, the dielectric layer 225 includes a polymeric material, such as an epoxy material, acrylic, polyimide, cyanate esters, or UV curable materials, that can be deposited over the substrate. In some embodiments, the dielectric layer 225 can include a thermoplastic material. In one example, a deposition chamber is disposed within a multi-chamber processing tool that is configured to perform a slit coating process, a spray coating process, a spin-coating process, or a doctor-blade deposition process to deposit an epoxy-containing layer over the surface of the substrate.

At operation 605, as shown in FIG. 7B, a patterned layer formation process is performed on the deposited dielectric layer 225. The patterning process will include exposing portions of the deposited dielectric layer 225 to electromagnetic radiation, such as coherent radiation emitted from a laser source. In some embodiments, the processes performed during operation 605 are configured to generate the radiation-exposed portions of the deposited dielectric layer 225 that can be selectively removed versus unexposed regions of the deposited dielectric layer 225 during operation 605. In one example, the deposited dielectric layer 225 includes a photosensitive material, and the patterning process comprises scanning an IR or UV laser over sections of the deposited dielectric layer 225 positioned within a patterning chamber within a multi-chamber processing tool to form the radiation-exposed portions that can then be selectively removed to form features 227 within the deposited dielectric layer 225. Laser power, pulse duration, wavelength, and scanning speed are all used to control the type and extent of microstructural changes in the exposed deposited dielectric layer 225. A develop process is then used to selectively remove the radiation-exposed portions of the deposited dielectric layer 225 to form the features 227. The develop process can include exposing portions of the deposited dielectric layer 225 to a wet develop process and/or dry develop process.

At operation 610, one or more descum or cleaning processes are used to remove contamination found on the patterned surfaces of the patterned dielectric layer 225. The descum or cleaning processes can include wet and/or dry cleaning processes. In one example, a wet clean chamber is configured to perform a wet clean process to clean the surfaces of the patterned dielectric layer 225, exposed portions of the pillars 231 and/or contacts 210A of the electronic device 210 via a delivery of a fluid, such as water, a cleaning chemistry, or both, while the substrate 201 is rotated at desired revolutions-per-minute (RPM). The cleaning chemistry can include an acid, base, or solvent-containing solution configured to at least remove an oxide or organic material disposed on the exposed portions of the pillars 231 and/or contacts 210A of the electronic device 210 exposed within the formed features 227.

At operation 615, as shown in FIG. 7C, a first conductive layer 228 is formed over the field region of the dielectric layer 225 and the pillars 231 and/or contacts 210A of the electronic device 210 exposed within the features 227 formed within the patterned dielectric layer 225 by use of one or more material deposition processes. The one or more material deposition processes can include a physical vapor deposition (PVD) process, chemical vapor deposition (CVD) process, plasma enhanced CVD (PECVD) process, atomic layer deposition (ALD) process, plasma enhanced ALD (PEALD) process, an electroless deposition process, or other useful conductive layer deposition processes. In some embodiments, the first conductive layer 228 includes one or more metals that are selected from a group that includes copper (Cu), titanium (Ti), tantalum (Ta), aluminum (Al), cobalt (Co), ruthenium (Ru), molybdenum (Mo), silver (Ag), gold (Au), tungsten (W), and nickel (Ni) and can have a thickness of about 0.5 micrometer (μm) to about 10 μm, such as about 1 μm to about 7 μm. In one example, the first conductive layer 228 is a seed layer that includes copper (Cu) that has a thickness of about 5 μm and is deposited over the exposed contacts 210A and pillars 231 within the features 227 and also exposed portions of the patterned dielectric layer 225 by use of a PVD process. The first conductive layer 228 deposition process can be performed within a first metal deposition chamber within the multi-chamber processing tool.

At operation 620, as shown in FIG. 7D, a second conductive layer 229 is formed over the first conductive layer 228, in order to fill the features 227, by use of one or more material deposition processes. The deposited second conductive layer 229 can be used to form interconnect traces within the redistribution layer 122A of the interconnect layer 122. The one or more material deposition processes can include a physical vapor deposition (PVD) process, an electroplating process, an electroless deposition process, or other useful conductive layer deposition processes. In some embodiments, the second conductive layer 229 includes one or more metals that are selected from a group that includes copper (Cu), titanium (Ti), tantalum (Ta), aluminum (Al), cobalt (Co), ruthenium (Ru), molybdenum (Mo), silver (Ag), gold (Au), tungsten (W), and nickel (Ni). In one example, the second conductive layer 229 includes a copper layer that is deposited over the field region and within the features 227 by use of an electroplating process. In some examples, the as-deposited interconnect traces within the redistribution layer 122A can have a thickness 229A of about 1 μm to about 20 μm, such as about 2 μm to about 10 μm. In one example, the formed interconnect traces include a copper layer that has a thickness 229A of about 5 μm and is deposited so as to connect a first contact 210A of the electronic device 210 to one or more pillars 231 or other interconnecting elements (not shown) within the redistribution layer 122A. The second conductive layer deposition process can be performed within the second metal deposition chamber within the multi-chamber processing tool.

Next, at operation 625, as shown in FIG. 7E, the first conductive layer 228, second conductive layer 229, and exposed portions of the dielectric layer 225 are planarized by use of one or more material removal processes to form a substantially planar surface 236. Due to the rigidity and planar surface characteristics (e.g., surface topography) of the first substrate 201, the process of planarizing the surface of the substrate allows the planar surface 236 to include minimal topography or surface variation. In some embodiments of operation 625, the one or more material removal processes include a grinding and/or polishing process, such as a chemical mechanical polishing (CMP) process. In one example, operation 625 includes a CMP process that is configured to form the planar surface 236 that has a peak-to-peak flatness between about 1 micrometers (μm) and 100 (μm). In one example, the one or more material removal processes are configured to remove the portions of the first conductive layer 228 disposed on the field regions of the dielectric layer 225 and portions of the second conductive layer 229, and expose portions of the dielectric layer 225 by use of a CMP process to form the planar surface 236. In one example, after performing operation 625, the interconnect traces formed within the redistribution layer 122A have a thickness 236A that is less than the thickness 229A and can have a thickness of about 1 μm to about 15 μm, such as about 2 μm to about 10 μm. Therefore, the processes performed during operation 625 are performed to significantly reduce the thickness variation across the thickness of the substrate 201 and planarize portions of the interconnect traces of the redistribution layer 122A. The processes performed during operation 625 can be used to improve the yield of the die-to-substrate bonding process due to the high degree of flatness or coplanarity of the surfaces in the formed package, and also provide improved warpage control.

After performing method 600 a first time, depending on the desired number of redistribution layers that are to be formed within an interconnect layer, method 600 can be repeated one or more additional times to form a stack of redistribution layers that is configured to interconnect the various devices within the device containing layers within device layer stack 120. In one example, as shown in FIGS. 7F-7J, method 600 is performed a second time to form a second redistribution layer 122B over the first redistribution layer 122A of the interconnect layer 122.

During the second performance of operation 601, a dielectric layer 234 is deposited over the surface of the first redistribution layer 122A and device containing layer 121, as shown in FIG. 7F. The dielectric layer material and deposition process used to form the dielectric layer 234 can include the same dielectric layer material and deposition process used to form the dielectric layer 225 of the first redistribution layer 122A. In one example, the dielectric layer 234 includes a polymeric material, such as an epoxy material, acrylic, polyimide, cyanate esters, or UV curable materials, that can be deposited over the substrate.

During the second performance of operation 605, as shown in FIG. 7G, a patterned layer formation process is performed on the deposited dielectric layer 234. The patterning process will include exposing portions of a deposited dielectric layer 234 to electromagnetic radiation, such as coherent radiation emitted from a laser source. The processes performed during the second performance of operation 605 are configured to generate the radiation-exposed portions of the deposited dielectric layer 234 that are configured to form interconnecting features 237 within the dielectric layer 234 that are coupled to interconnecting features formed in the first redistribution layer 122A. The dielectric layer patterning process used to form the features 237 in dielectric layer 234 can include the same patterning process steps used to form the features 227 in the dielectric layer 225 of the first redistribution layer 122A, and thus will not be recited again herein. In some embodiments, the features 237 include via-shaped openings that are used to interconnect the first redistribution layer 122A traces to traces formed in a subsequently formed redistribution layer.

The second performance of operation 610 can include one or more descum and/or cleaning processes that are used to remove contamination found on the patterned surfaces of the patterned dielectric layer 234. The descum or cleaning processes performed during the second performance of operation 610 can include the same processes used to descum or clean at least the surfaces of the features 227 in the dielectric layer 225 of the first redistribution layer 122A. The cleaning chemistry used during operation 610 can include an acid, base, or solvent-containing solution configured to at least remove an oxide or organic material disposed on the exposed portions of the traces formed in the first redistribution layer 122A.

During the second performance of operation 615, as shown in FIG. 7H, a first conductive layer 238 of the second redistribution layer 122B is formed over the field region of the dielectric layer 234 and exposed portions of the traces within the first redistribution layer 122A by use of one or more material deposition processes. The first conductive layer 238 deposition process will include the same processing steps and conductive materials used to form the first conductive layer 228 in the first redistribution layer 122A, and thus will not be recited again herein. In some embodiments, the first conductive layer 238 has a thickness of about 0.5 micrometer (μm) to about 10 μm, such as about 1 μm to about 7 μm. In one example, the first conductive layer 238 is a seed layer that includes copper (Cu) that has a thickness of about 5 μm and is deposited over the traces of the first redistribution layer 122A exposed within the features 237 and also exposed portions of the patterned dielectric layer 234 by use of a PVD process. The first conductive layer 238 deposition process can be performed within a first metal deposition chamber within the multi-chamber processing tool.

The second performance of operation 620, as shown in FIG. 7I, can include the formation of a second conductive layer 239 over the first conductive layer 238 by use of one or more material deposition processes. The deposited second conductive layer 239 can be used to form interconnect traces within the second redistribution layer 122B of the interconnect layer 122. The second conductive layer 239 deposition process will include the same processing steps and conductive materials used to form the second conductive layer 229 in the first redistribution layer 122A, and thus will not be recited again herein. In some examples, the interconnect traces within the second redistribution layer 122B can have a thickness 239A of about 1 μm to about 20 μm, such as about 2 μm to about 10 μm. In one example, the formed interconnect traces include a copper layer that has a thickness 239A of about 5 μm and is deposited so as to connect one or more traces within the redistribution layer 122A to any subsequently formed interconnecting traces. The second conductive layer deposition process can be performed within the second metal deposition chamber within the multi-chamber processing tool.

The second performance of operation 625, as shown in FIG. 7J, can include the first conductive layer 238, second conductive layer 239, and exposed portions of the dielectric layer 234 are planarized by use of one or more material removal processes to form a substantially planar surface 241. In one example, the one or more material removal processes are configured to remove the portions of the first conductive layer 238 disposed on the field regions of the dielectric layer 234 and portions of the second conductive layer 239, and expose portions of the dielectric layer 234 by use of a CMP process to form the planar surface 241. The planarization process performed during the second performance of operation 625 will include the same processing steps used to planarize the surface of the first redistribution layer 122A as described above in relation to the first performance of operation 625, and thus will not be recited again herein. At the completion of the second performance of operation 625, the planarized surface 241 will include exposed portions of a plurality of conductive traces 242 that include portions of the first conductive layer 238 and the second conductive layer 239. In one example, after performing operation 625, the interconnect traces formed within the redistribution layer 122B have a thickness 241A that is less than the thickness 239A and can have a thickness of about 1 μm to about 15 μm, such as about 2 μm to about 10 μm.

FIG. 7K illustrates an example of a formed device layer structure, such as the first device layer structure 105 illustrated in FIG. 5. The first device layer structure 105 illustrated includes a third redistribution layer 122C formed over the second redistribution layer 122B by performing the operations within method 600 a third time. The third redistribution layer 122C includes a third dielectric layer 245 that includes a plurality of conductive traces 244 that are formed within features 247 formed in the third dielectric layer 245. The plurality of conductive traces 244 are coupled to the conductive traces 242 formed in the second redistribution layer 122B.

### Additional Device Containing Layer Formation Process Examples

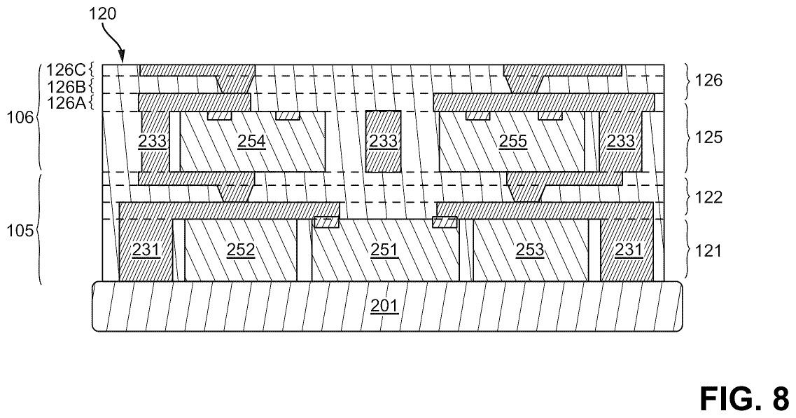

FIG. 8 is a side cross-sectional view of a portion of the device layer stack 120 that includes a second device layer structure 106 formed over the first device layer structure 105. The second device layer structure 106 includes a second device containing layer 125 and a second interconnect layer 126 that is disposed over the surface of the third distribution layer 122C of the first interconnect layer 122 of the first device layer structure 105. The second device containing layer 125 includes two electronic devices 254 and 255, and pillars 233. The two electronic devices 254 and 255 can be similarly configured as the two electronic devices 114 and 115 shown in FIG. 1A, which can include one or more integrated circuit (IC) devices (e.g., dies or chiplets) and/or dummy devices. The second interconnect layer 126 includes a plurality of redistribution layers, such as the redistribution layers 126A-126C.

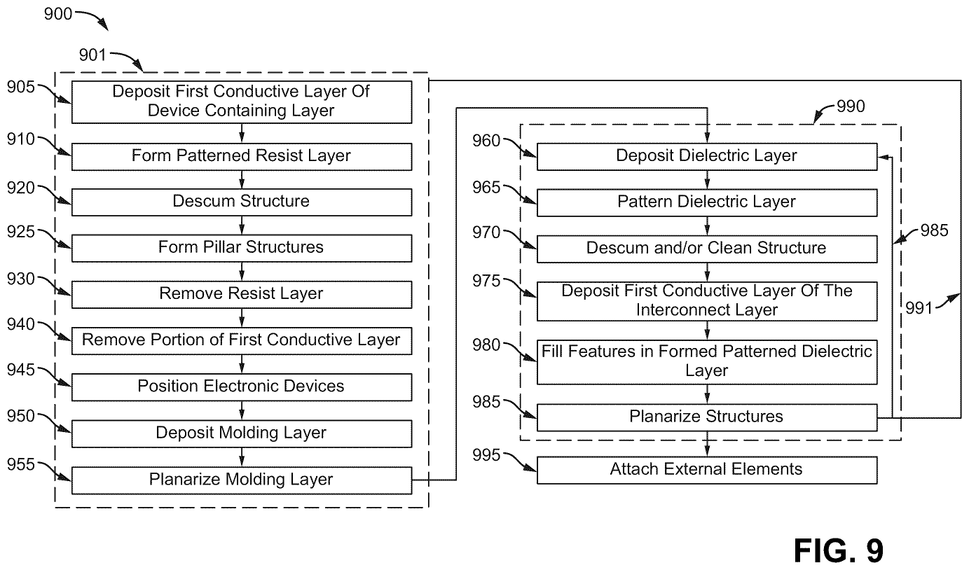

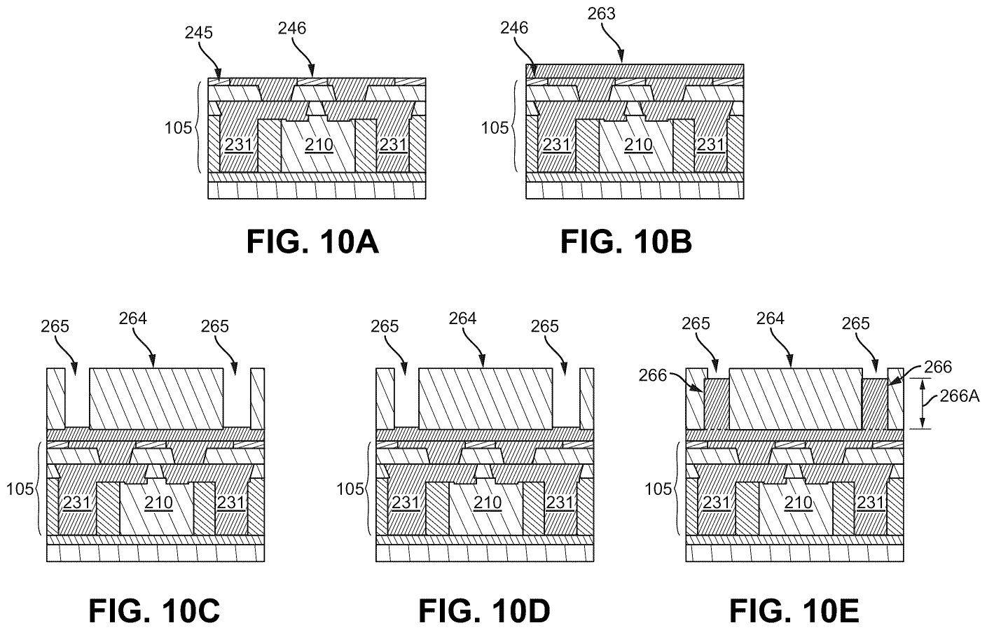

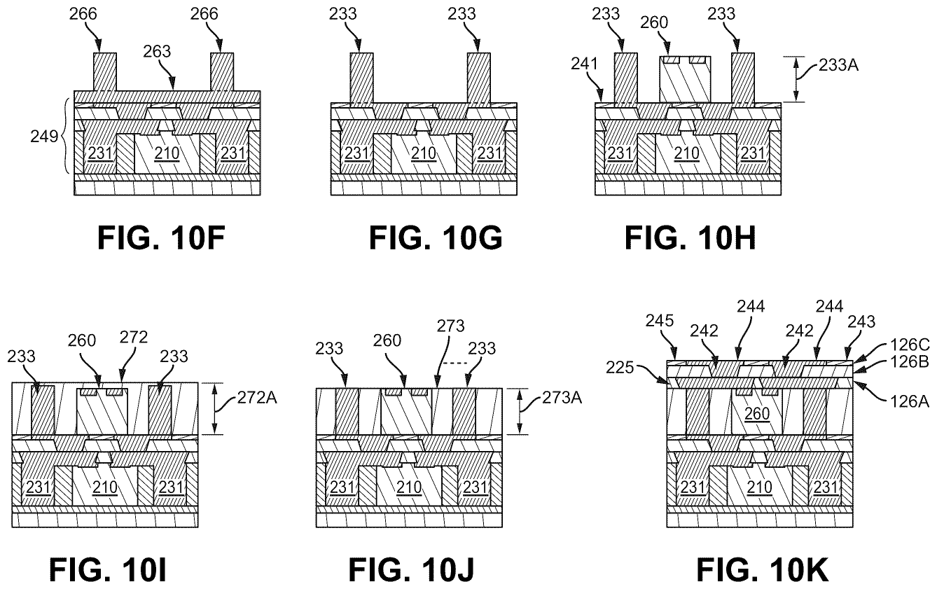

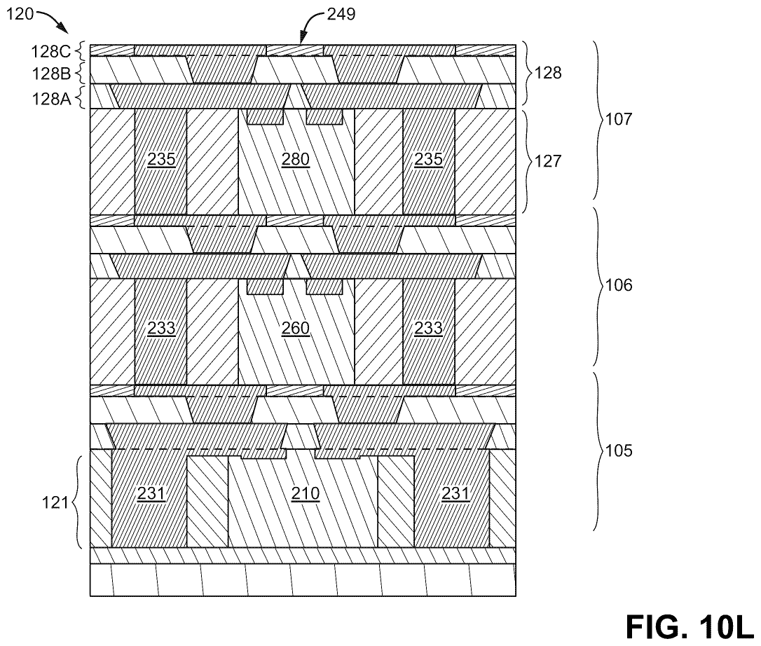

FIG. 9 is a process flow diagram that includes a method 900 that is configured to form an additional device layer structure (e.g., second device layer structure 106) over a previously formed device layer structure. The method 900 includes a first method 901 that is used to form a device containing layer within the additional device layer structure, and a second method 990 that is used to form one or more redistribution layers within an interconnect layer that is formed over the additional device containing layer, according to one or more embodiments. In one example, method 901 is used to form the second device containing layer 125 over the first device layer structure 105, and method 990 is used to form the second interconnection layer 126 over the second device containing layer 125. FIGS. 10A-10J are cross-sectional views of the device containing layer 123 within the three-dimensional (3D) device package during different stages of the method 901, illustrated in FIG. 9. FIG. 10A illustrates the first device layer structure 105 that includes three redistribution layers formed over a device containing layer that is positioned over a substrate, as illustrated in FIGS. 5 and 7K.

The operations performed in methods 901 and 990 of method 900 can be performed multiple times, as illustrated by the recursive path 991, to form a device layer stack 120 that includes two or more device layer structures. In one example, the operations within method 900 were repeated at least two times to form the device containing layers 125, 127, and interconnection layers 126, 128 within the device layer structures 106 and 107 illustrated in FIG. 1A.

At operation 905, as shown in FIG. 10B, a first conductive layer 263 of the second device containing layer 125 is formed over the exposed surfaces of the first device layer structure 105 by use of one or more material deposition processes. The one or more material deposition processes can include a physical vapor deposition (PVD) process, chemical vapor deposition (CVD) process, plasma enhanced CVD (PECVD) process, atomic layer deposition (ALD) process, plasma enhanced ALD (PEALD) process, an electroless deposition process, or other useful conductive layer deposition processes. In some embodiments, the first conductive layer 263 includes one or more metals that are selected from a group that includes copper (Cu), titanium (Ti), tantalum (Ta), aluminum (Al), cobalt (Co), ruthenium (Ru), molybdenum (Mo), silver (Ag), gold (Au), tungsten (W), and nickel (Ni) and can have a thickness of about 0.5 micrometer (μm) to about 10 μm, such as about 1 μm to about 7 μm. In one example, the first conductive layer 263 is a seed layer that includes copper (Cu) that has a thickness of about 5 μm and is deposited over the surfaces of the first device layer structure 105 by use of a PVD process. The first conductive layer 263 deposition process can be performed within the first metal deposition chamber within the multi-chamber processing tool.

At operation 910, as shown in FIG. 10C, a patterned layer formation process is performed over the formed first conductive layer 263. The patterned layer formation process will include exposing portions of a resist layer 264 to electromagnetic radiation, such as coherent radiation emitted from a laser source. In some embodiments, the processes performed during operation 910 are configured to generate the radiation-exposed portions of the resist layer 264 that can be selectively removed versus unexposed regions of the resist layer 264 to form the openings 265 within the patterned resist layer. The patterned layer formation process performed during operation 910 will include the same processing steps used to form the pattern layer described above in relation to operation 310 of method 300, and thus will not be recited again herein.

At operation 920, as shown in FIG. 10D, one or more descum or cleaning processes are used to remove contamination found on the surfaces of the patterned resist layer 264. The descum or cleaning processes can include wet and/or dry cleaning processes. In one example, a wet clean chamber is configured to perform a wet clean process to clean the surfaces of the patterned resist layer, and exposed portions of the first conductive layer 263 exposed within the openings 265 via delivery of a fluid, such as water, a cleaning chemistry, or both, while the substrate 201 is rotated at desired revolutions-per-minute (RPM). The cleaning chemistry can include an acid, base, or solvent-containing solution configured to at least remove an oxide or organic material disposed on the exposed portions of the first conductive layer 263 exposed within the openings 265.

At operation 925, as shown in FIG. 10E, a second conductive layer 266 of the second device containing layer 125 is formed within the openings 265 formed in the resist layer 264 by use of one or more material deposition processes. The deposited second conductive layer 266 forms pillars 233 (FIGS. 8 and 10G) within the second device containing layer 125. The one or more material deposition processes can include a physical vapor deposition (PVD) process, an electroplating process, an electroless deposition process, or other useful conductive layer deposition processes. In some embodiments, the second conductive layer 266 includes one or more metals that are selected from a group that includes copper (Cu), titanium (Ti), tantalum (Ta), aluminum (Al), cobalt (Co), ruthenium (Ru), molybdenum (Mo), silver (Ag), gold (Au), tungsten (W), and nickel (Ni). In one example, the second conductive layer 266 includes a copper layer that is deposited within the openings 265 by use of an electroplating process. The thickness of the deposited second conductive layer 266 is selected such that the thickness is at least as thick as a die or chiplet (e.g., electronic device 254 or 255 in FIG. 8) that is to be positioned within the second device containing layers 125 in a subsequent operation. In some examples, the formed pillars can have a thickness 266A of about 25 μm to about 100 μm, such as about 40 μm to about 80 μm. In one example, the conductive layer 266 includes a copper layer that has a thickness of about 50 μm and is deposited over the exposed portion of conductive layer 263 within the openings 265 by use of an electroplating process. The conductive layer 266 deposition process can be performed within a second metal deposition chamber within the multi-chamber processing tool.

At operation 930, as shown in FIG. 10F, the patterned resist layer 264 is removed to expose a portion of the first conductive layer 263 and the second conductive layer 266. The patterned resist layer removal processes can include exposing portions of the resist layer 264 to a conventional resist removal process, which can include a wet etching process (e.g., solvent containing fluid) and/or dry etching process (e.g., oxygen plasma). The patterned resist layer removal process can be performed within a processing chamber within the multi-chamber processing tool.

At operation 940, as shown in FIG. 10G, exposed portions of the first conductive layer 263 are removed from the surface of the first device layer structure 105 to form the pillars 233. The material removal processes can include exposing portions of the first conductive layer 263 and second conductive layer 266 to a wet etching process and/or dry etching process to remove the exposed portions of the first conductive layer 263 disposed between the deposited portions of the second conductive layer 266. The pillars 233 form structural features with the second device containing layer 125 and portions of interconnects that are coupled to one or more electronic devices within the second device containing layer 125. In some embodiments of operation 940, the first conductive layer 263 is not selectively removed relative to the material formed within the second conductive layer 266 and thus the thickness 266A of the second conductive layer 266 is selected, during operation 925, to assure that the height 233A (FIG. 10H) of the formed pillars 233 is at least as large as the thickness of the die or chiplet (e.g., electronic device 254 or 255) that is to be positioned within the second device containing layer 125 during operation 945. The first conductive layer material removal process can be performed within a processing chamber within the multi-chamber processing tool.

Next, at operation 945, one or more electronic devices are positioned over a portion of the first device layer structure 105 and between and/or adjacent to a pillar 233 formed within the pillar structure formed over the surface 241 of the first device layer structure 105. In one example, as shown in FIG. 10H, an electronic device 260 is positioned between adjacent pillars 233. As discussed above, an electronic device that can be positioned during operation 945 can include positioning a die or chiplet, passive device, or dummy device. The thickness of the electronic device will typically be equal to or less than the height 233A of the formed pillar 233, which is created during the performance of operations 905-940.

At operation 950, a molding layer is deposited over the surface of the partially formed second device containing layer 125, which includes the pillars 233 and electronic device 260, as shown in FIG. 10I. The molding process will include the deposition of molding material 272 by use of, for example, a spin-coating process, printing process, or doctor-blade deposition process. In one example, the molding material 272 includes a polymeric material, such as an epoxy material, acrylic, polyimide, cyanate esters, or UV curable materials, that can be deposited over the substrate. In some embodiments, the molding material 272 can include a thermoplastic material. In one example, a molding material deposition chamber is disposed within a multi-chamber processing tool that is configured to perform a slit coating process, a spray coating process, a molding process, a spin-coating process, or a doctor-blade deposition process to deposit an epoxy-containing layer over the surface of the substrate. In some embodiments of operation 950, the thickness 272A of the deposited molding layer is selected to assure that the thickness 272A of the molded layer is at least as large as the thickness of the die or chiplet (e.g., electronic device 254 or 255).

Next, at operation 955, as shown in FIG. 10J, the molding material layer, pillars 233, and upper surface of the electronic devices are planarized by use of one or more material removal processes to form a substantially planar surface 273. Due to the rigidity and planar surface characteristics (e.g., surface topography) of the first substrate 201, the process of planarizing the surface of the substrate allows the planar surface 213 to include minimal topography or surface variation. In some embodiments of operation 955, the one or more material removal processes include a grinding and/or polishing process, such as a chemical mechanical polishing (CMP) process. The planarization process performed during operation 955 will include the same processing steps used to planarize a surface of the first device containing layer 121 described above in relation to operation 355 of method 300, and thus will not be recited again herein. However, in one example, the one or more material removal processes are configured to remove portions of the pillars 233 and contacts 260A of the electronic device 260 by use of a CMP process to form the planar surface 273. In some embodiments of operation 955, the thickness 273A of the second device containing layer 125, after performing operation 955, is selected to assure that portions of the pillars 233 and contacts 260A of the electronic device 260 (e.g., electronic device 254 or 255) are exposed.

After performing method 901, method 900 then proceeds on to method 990 in which one or more redistribution layers are formed over the device layer structure formed during method 901. The operations 960-985 of method 990 utilize the same materials and processes described in operations 601-625 of method 600, and, as discussed above, can be repeated multiple times to form one or more redistribution layers within an interconnect layer.

FIG. 10K illustrates an example of a formed device layer structure, such as the second device layer structure 106 illustrated in FIG. 8. The second device layer structure 106 illustrated in FIG. 10K includes an interconnect layer 126 that includes three redistribution layers 126A-126C that are formed over the second device containing layer 125 by sequentially performing the operations within method 990 three times. The three redistribution layers 126A-126C include patterned dielectric layers and conductive traces that are used to interconnect the electronic devices 254, 255 to the other electrical components within the device layer stack 120 as similarly discussed in relation to method 600. In one example, the plurality of conductive traces 244 formed in the second redistribution layer 126B are coupled to the conductive traces 242 formed in the first redistribution layer 126A. The exposed surface 243 of the formed interconnect layer 126 can be used as a support and interface for a subsequently formed device containing layer.

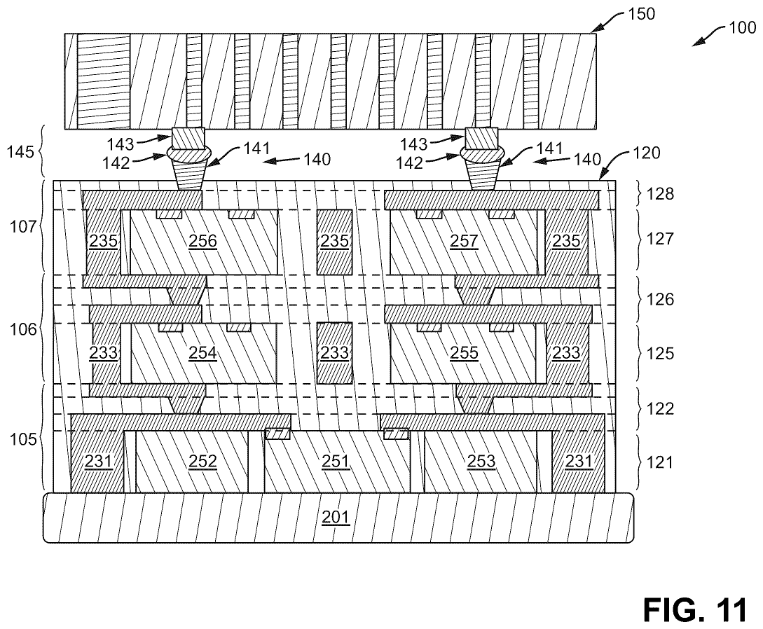

FIG. 10L illustrates an example of device layer stack 120 that includes a second additionally formed device layer structure, such as the third device layer structure 107, that is formed over the previously formed first device layer structure 105 and second device layer structure 106. FIG. 11 is cross-sectional view of a device layer stack 120 that includes three device containing layers 105-107, which is similar to the device layer stack 120 example illustrated in FIG. 10L but additionally illustrates the incorporation of multiple electronic devices within each of the device layer structures 105-107. The third device layer structure 107 illustrated in FIGS. 10L and 11 includes an interconnect layer 128 that includes multiple redistribution layers, such as three redistribution layers 128A-128C shown in FIG. 10L, that are formed over a third device layer 127 by sequentially performing the operations within method 901 once and the operations within method 990 multiple times. The third device containing layer 127 includes a plurality of electronic devices, such as the electronic devices 256 and 257 shown in FIG. 11, that are disposed between the pillars 235 that are formed during the completion of method 901. The three redistribution layers 128A-128C include patterned dielectric layers and conductive traces that are used to interconnect the electronic devices, such as electronic devices 256 and 257 of FIG. 11, to the other electrical components within the device layer stack 120 as similarly discussed in relation to method 600 and method 990.

As previously discussed and shown in FIG. 11, the device layer stack 120 can be coupled to one or more external devices, such as an inductor, by use of interconnects 140 that each can include a contact 141, solder ball 142, and contact 143 of the electrical component 150 that are disposed within an interconnect region 145. The contact 141 is coupled to, or forms part of, conductive regions formed within at least one of the redistribution layers 128A-128B within the interconnect layer 128.

### Backside Interconnect Formation Example

In some three-dimensional (3D) device package designs, such as package-on-package (PoP) device packages, it is desirable to form connections on both sides of one or more electronic devices disposed within a device layer stack 120.

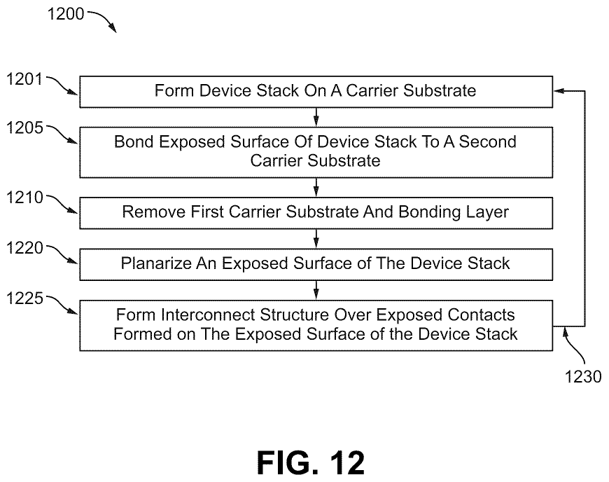

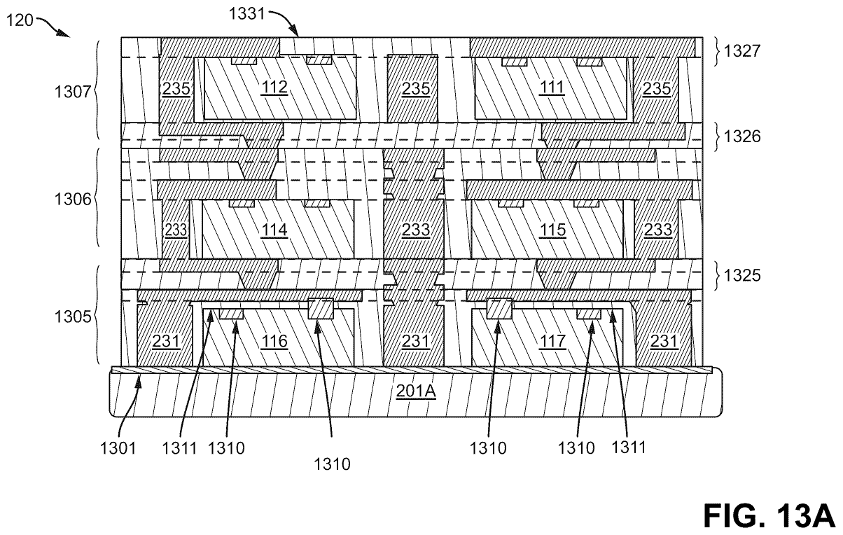

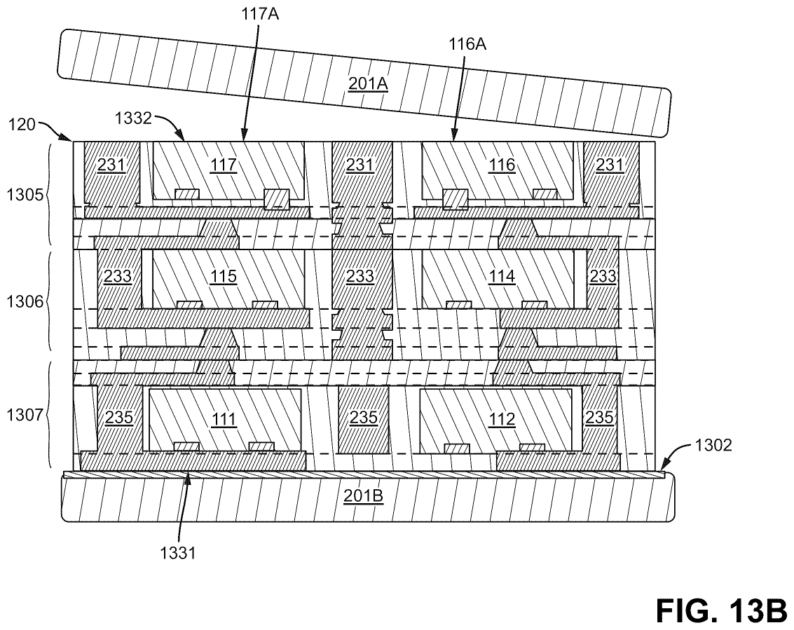

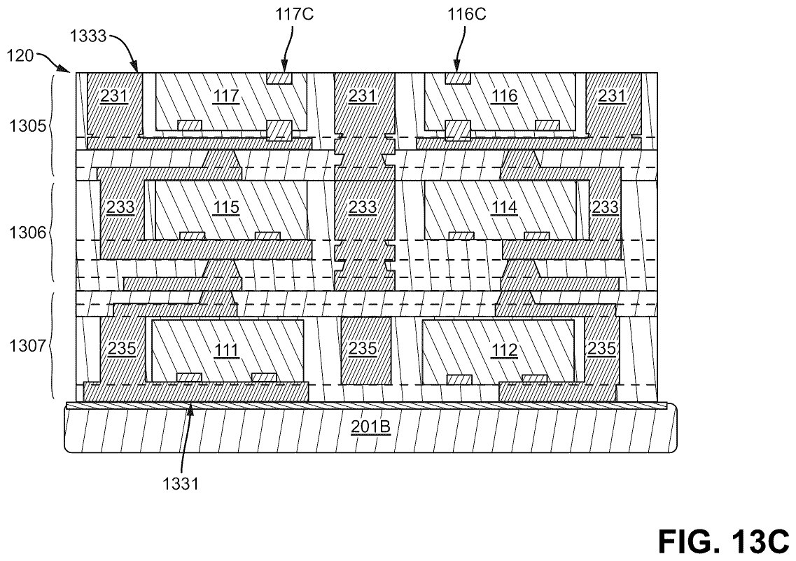

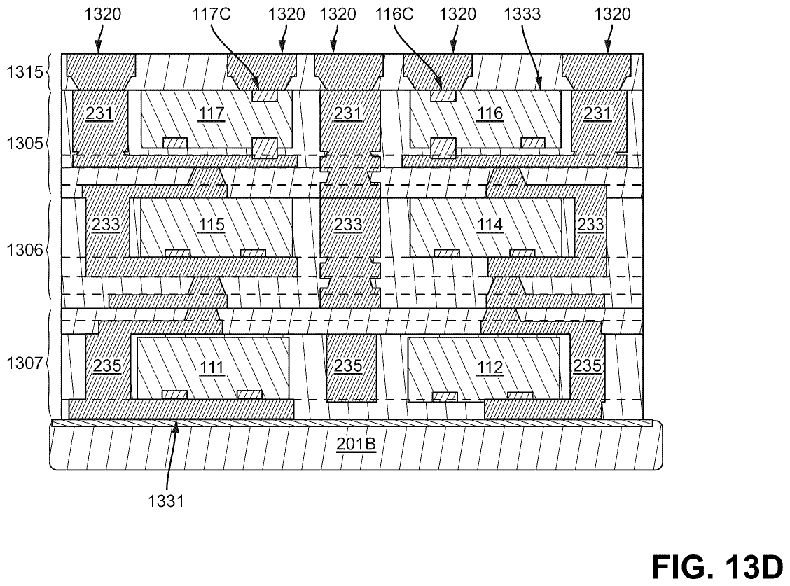

FIG. 12 depicts an example of a backside interconnect formation process, which is referred to herein as method 1200, that can be used to form an interconnect layer 1315 (FIG. 13D) over a backside surface of a device layer structure (e.g., device layer structure 1305 in FIGS. 13A-13D) within a device layer stack 120.

At operation 1201, a device layer stack 120 is formed over a surface of a first carrier substrate 201A by, for example, use of one or more of the methods 300, 600, and 900 that are described herein. FIGS. 13A-13D are cross-sectional views of portions of a device layer stack 120 that depict different stages of the operations performed during the completion of method 1200. FIG. 13A is a side cross-sectional view of a device layer stack 120 that includes a first device layer structure 1305, a second device layer structure 1306, and a third device layer structure 1307. In this example, the device layer structures 1305, 1306, 1307 each includes electronic devices that are interconnected by use of one or more redistribution layers formed within the interconnect layers 1325, 1326, 1327. In one example, as shown in FIGS. 13A-13D, the device containing layers within the device layer structures 1305, 1306, 1307 each includes two integrated electronic devices (e.g., dies or chiplets), a pillar structure, and one or more interconnecting vias (not shown) that extend through the device containing layers.

As shown in FIG. 13A, the device containing layer within the first device layer structures 1305 includes two electronic devices 116 and 117, and two pillars 231. The electronic devices 116, 117 can each include a die, a chiplet, a passive component (e.g., capacitor), or a dummy device. In one example, as discussed above, the electronic devices 116, 117 include two dies or chiplets, such as a first MOSFET and a second MOSFET, which can include a low-frequency MOSFET and a high-frequency MOSFET, respectively. In this example, the two electronic devices 116, 117 include a plurality of contacts 1310 formed on a first surface 1311 of the electronic devices 116, 117. At least one of the two electronic devices 116, 117 within the device containing layer is interconnected to one or more of the other electrical components disposed within the device layer structures 1306, 1307 by use of the redistribution layers formed within the interconnect layer 1325.

The device containing layer within the second device layer structures 1306 includes two electronic devices 114 and 115, and pillars 233. The electronic devices 114, 115 can each include a die, a chiplet, a passive component (e.g., capacitor), or a dummy device. In one example, the electronic devices 114, 115 include two passive components, such as two capacitors. At least one of the two electronic devices 114, 115 within the device containing layer is interconnected to one or more of the other electrical components disposed within the device layer structures 1305, 1307 by use of the redistribution layers formed within the interconnect layer 1306.

The device containing layer within the third device layer structures 1307 includes two electronic devices 111 and 112, and pillars 235. The electronic devices 111, 112 can each include a die, a chiplet, a passive component (e.g., capacitor), or a dummy device. In one example, at least one of the two electronic devices 111, 112 includes a control die. At least one of the two electronic devices 111, 112 within the device containing layer is interconnected to one or more of the other electrical components disposed within the device layer structures 1305, 1306 by use of the redistribution layers formed within the interconnect layer 1327.

At operation 1205, a second bonding layer 1302 (FIG. 13B shown flipped from FIG. 13A) is applied to a surface 1331 of the device layer stack 120 (FIG. 13A) by use of a bonding layer deposition process, and a second carrier substrate 201B is positioned on the formed second bonding layer 1302. The second carrier substrate 201B can include a glass sheet, a silicon substrate, a metal substrate, or a ceramic substrate that has a desired size to receive the device layer stack 120. The second bonding layer 1302 includes a material or materials selected to allow the exposed surface of the bond layer 1302 to form a detachable bond between a surface of the substrate 201B and surface 1331 of the device layer stack 120. In one example, the bonding layers 1302 include a polymeric material, such as an epoxy material, acrylic, polyimide, cyanate esters, or UV curable materials, that can be deposited on the surface 1331 by use of spin-coating process, printing process or doctor-blade deposition process.

At operation 1210, the first carrier substrate 201A is separated from the device layer stack 120 by breaking the adhesive bond created between the first carrier substrate 201A and the device layer stack 120 by the first bonding layer 1301 (FIG. 13A). The process of separating the first carrier substrate 201A from the device layer stack 120 is used to expose a surface 1332 of the device layer stack 120 that is adjacent to the backside surfaces of the electronic devices, such as the backside surfaces 116A, 117A of the electronic devices 116, 117, that were positioned adjacent to bonding layer 1301 and upper surface of the first carrier substrate 201A. The process of separating the first carrier substrate 201A from the device layer stack 120 can be performed by a thermal process, an etching process, or a mechanical separation process. In some cases, it is desirable to remove any residual first bonding layer material from the surface 1332 by use of a wet etch or dry etch cleaning process.

Next, at operation 1220, as shown in FIG. 13C, the surface 1332, which includes the surfaces 116A, 117A of the electronic devices (shown in FIG. 13B), is planarized by use of one or more material removal processes to form a substantially planar surface 1333. In some embodiments of operation 1220, the one or more material removal processes include a grinding and/or polishing process, such as a CMP process. The one or more material removal processes are configured to planarize the surface of the device layer stack 120 and remove portions of the electronic devices 116, 117 to expose contacts 116C, 117C within the electronic devices 116, 117 or expose regions of the electronic devices 116, 117 that will allow the contacts 116C, 117C to be subsequently formed. In some embodiments of operation 1220, the contacts 116C and/or 117C are cleaned, dried, and/or a conductive layer is formed thereover after performing the planarization process to assure a desirable contact can be formed in a subsequent processing step.

Next, at operation 1225, as shown in FIG. 13D, an interconnect layer 1315 is formed over the substantially planar surface 1333 to allow at least one of the contacts 116C, 117C to be interconnected to one or more of the other electrical components disposed within the device layer structures 1305, 1306, 1307, electrical components 150, and/or other external electrical components by use of the redistribution layers formed within the interconnect layer 1315. The interconnect layer 1315 can be formed by use of operations 960-985 of method 990 to form the one or more redistribution layers within the interconnect layer 1315. The interconnect layer 1315 can include a plurality of contacts 1320, in which one or more of the contacts 1320 are coupled to a pillar (e.g., pillar 231), a first contact 116C, and a second contact 117C.

### Device Layer Stack Formation Process Example

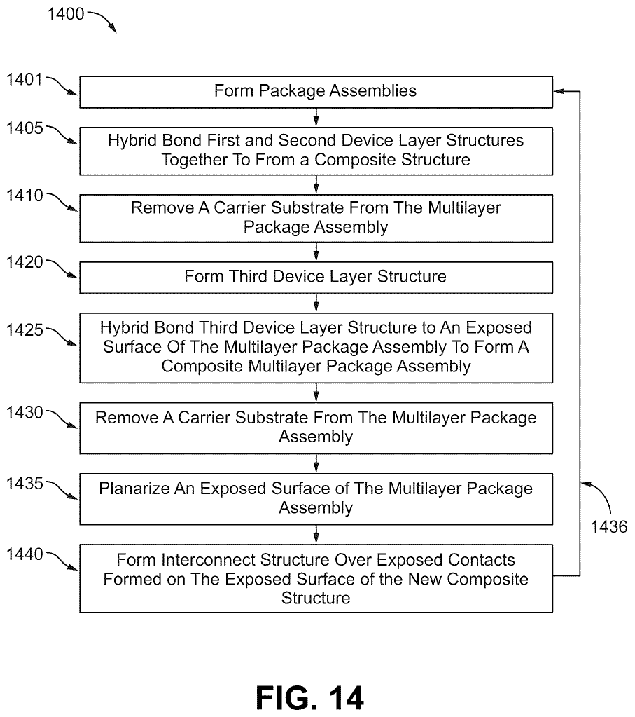

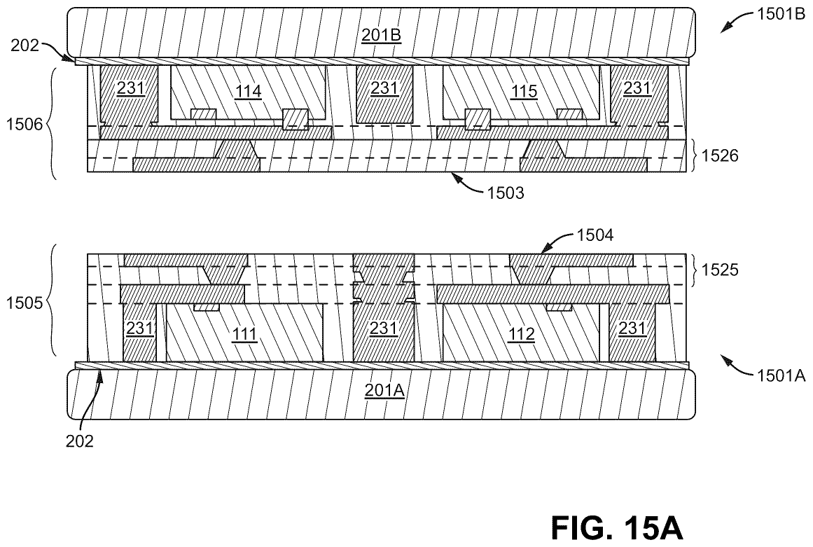

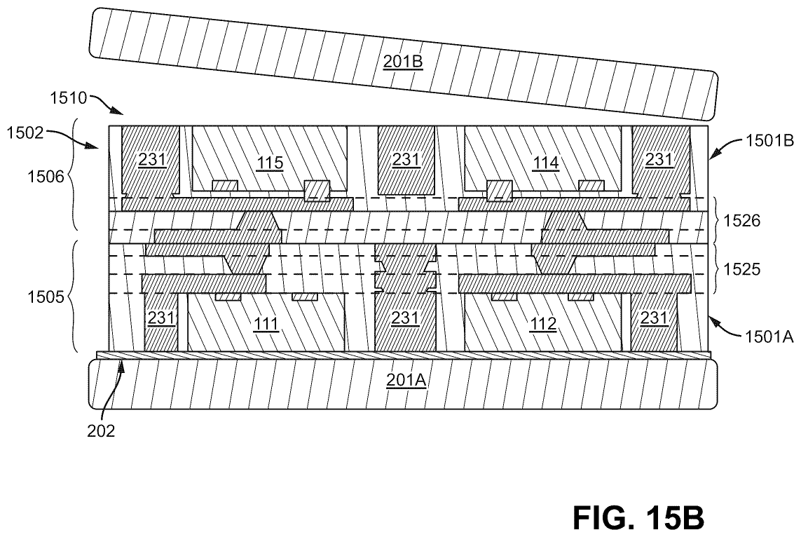

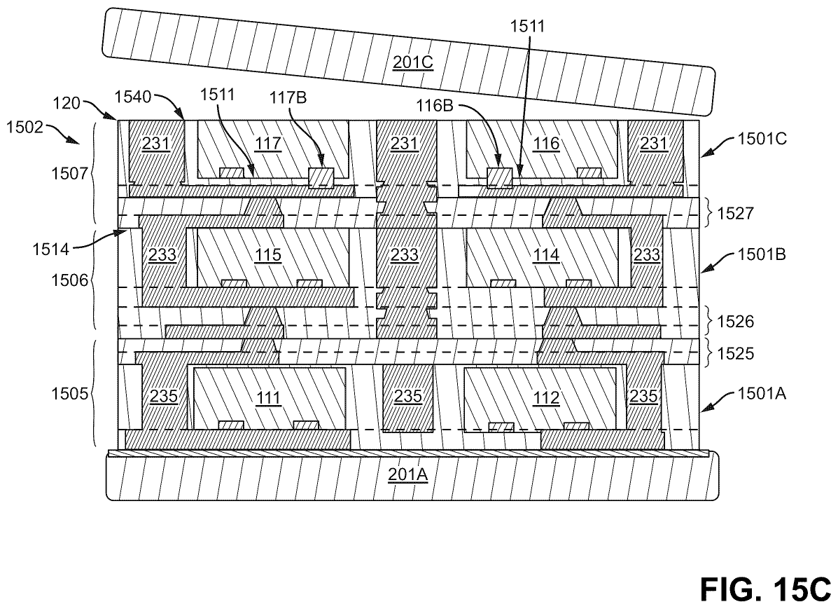

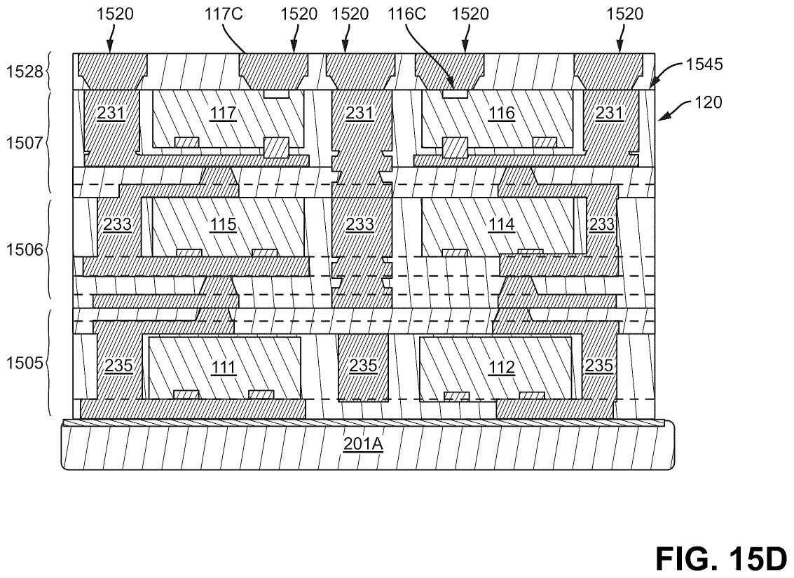

FIG. 14 depicts an alternate example of a device layer stack 120 formation process that includes a plurality of device containing layers, which is referred to herein as method 1400. The method 1400 generally includes a process sequence that includes forming multiple package assemblies that each includes one or more device containing layers formed over the surface of a carrier substrate, and then hybrid bonding surfaces of two of the package assemblies together to form a multilayer package assembly. FIGS. 15A-15D are cross-sectional views of the device layer stack 120 during different stages of the method 1400.

Method 1400 starts at operation 1401, in which a plurality of package assemblies 1501 are formed. A package assembly 1501 includes at least one device containing layer formed over a surface of a first carrier substrate 201. FIGS. 15A-15D are cross-sectional views that depict various portions of a device layer stack 120 at different stages of the completion of method 1400.

FIG. 15A is a side cross-sectional view of two package assemblies 1501, such as a first package assembly 1501A that includes a first device layer structure 1505 formed over a first carrier substrate 201A and a second package assembly 1501B that includes a second device layer structure 1506 formed over a second carrier substrate 201B. In this example, the device layer structures 1505, 1506 each include electronic devices that are interconnected by use of one or more redistribution layers formed within interconnect layers 1525, 1526. In one example, as shown in FIGS. 15A-15D, the device containing layers within the device layer structures 1505, 1506, 1507 each includes two integrated electronic devices (e.g., dies or chiplets), a pillar structure, and one or more interconnecting vias (not shown) that extend through the device containing layers. A package assembly 1501, such as the first package assembly 1501A and the second package assembly 1501B, includes at least one device containing layer that is formed over a surface of a carrier substrate 201A, 201B by, for example, use of one or more of the methods 300, 600, and 900 described herein.

As shown in FIG. 15A, the device containing layer within the first device layer structures 1505 of the first package assembly 1501A includes two electronic devices 111 and 112, and pillars 231. The electronic devices 111, 112 can each include a die, a chiplet, a passive component (e.g., capacitor), or a dummy device. In one example, at least one of the two electronic devices 111, 112 includes a control die. At least one of the two electronic devices 111, 112 within the device containing layer is interconnected to one or more of the other electrical components disposed within the device layer structure 1505 by use of the redistribution layers formed within the interconnect layer 1525. The device containing layer within the second device layer structures 1506 of the second package assembly 1501B includes two electronic devices 114 and 115, and pillars 231. The electronic devices 114, 115 can each include a die, a chiplet, a passive component (e.g., capacitor), or a dummy device. In one example, the electronic devices 114, 115 include two passive components, such as two capacitors. At least one of the two electronic devices 114, 115 within the device containing layer is interconnected to one or more of the other electrical components disposed within the device layer structure 1506 by use of the redistribution layers formed within the interconnect layer 1526.

Next, at operation 1405, the first package assembly 1501A and the second package assembly 1501B are bonded together to electrically couple one or more of the electrical components within the device layer structures within the package assemblies 1501A, 1501B together to form a multilayer package assembly 1502 (FIG. 15B). Operation 1405 can include a hybrid bonding process that causes electrical contacts exposed at the surface 1504 of the first device layer structure 1505 to be electrically coupled to the electrical contacts exposed at the surface 1503 of the second device layer structure 1506. In some embodiments of operation 1405, a surface cleaning process and a plasma activation process are performed on each of the surfaces 1503 and 1504 prior to performing the bonding process. In one or more examples, the pretreatment process can include a wet or dry pre-cleaning type of process and the plasma activation process can include exposing the surfaces 1503 and 1504 to a plasma that contains a process gas that comprises at least one of He, H2, N2, Ar, or O2. The bonding process can include performing a hybrid bonding process that includes bringing the surfaces 1503 and 1504 into intimate contact, applying a desired amount of force to the package assemblies 1501A, 1501B while the package assemblies 1501A, 1501B are heated to a bonding temperature that can be between 20° C. and 450° C., such as bonding temperatures between 50° C. and 250° C.

At operation 1410, the second carrier substrate 201B is separated from the device layer stack of the second device layer structure 1506 by breaking the adhesive bond created between the first carrier substrate 201B and the device layer stack by a bonding layer 202 (FIG. 15A). The process of separating the second carrier substrate 201B from the device layer stack of the second device layer structure 1506 is used to expose a surface 1510 of the device layer stack of the second device layer structure 1506. The process of separating the second carrier substrate 201B from the device layer stack of the second device layer structure 1506 can be performed by a thermal process, an etching process, or a mechanical separation process. In some cases, it is desirable to remove any residual first bonding layer material from the surface 1510 by use of a wet etch or dry etch cleaning process.

At operation 1420, in which a third plurality of package assemblies 1501C is formed. The third package assembly 1501C, includes a third device layer structure 1507 that is formed over a third carrier substrate 201C. In this example, the device layer structure 1507 includes electronic devices that are interconnected by use of one or more redistribution layers formed within the interconnect layer 1527. In one example, as shown in FIG. 15C, the device containing layers within the device layer structures 1507 includes two integrated electronic devices (e.g., dies or chiplets), a pillar structure, and one or more interconnecting vias (not shown) that extend through the device containing layers. A package assembly 1501C includes at least one device containing layer that is formed over a surface of a carrier substrate 201C by, for example, use of one or more of the methods 300, 600, and 900 described herein.

As shown in FIG. 15C, the device containing layer within the third device layer structures 1507 of the first package assembly 1501C includes two electronic devices 116 and 117, and pillars 231. The electronic devices 116, 117 can each include a die, a chiplet, a passive component (e.g., capacitor), or a dummy device. In one example, the electronic devices 116, 117 include two dies or chiplets, such as a first MOSFET and a second MOSFET. In this example, the two electronic devices 116, 117 include a plurality of contacts 116B, 117B formed on a first surface 1511 of the electronic devices 116, 117. At least one of the two electronic devices 116, 117 within the device containing layer is interconnected to one or more of the other electrical components disposed within the device layer structure 1507 by use of the redistribution layers formed within the interconnect layer 1527.

Next, at operation 1425, the multilayer package assembly 1502 (FIGS. 15B-15C) and the third package assembly 1501C are bonded together to electrically couple one or more of the electrical components within the device layer structures within the multilayer package assembly 1502 and the third package assembly 1501C together to add an additional layer to the multilayer package assembly 1502, which for clarity of discussion purposes is referred to herein as a composite multilayer package assembly. Operation 1425 can include a hybrid bonding process that causes electrical contacts exposed at an exposed surface 1514 of the third device layer structure 1507 of the third package assembly 1501C to be electrically coupled to the electrical contacts exposed at the exposed surface 1510 of the multilayer package assembly 1502 formed during operation 1410. In some embodiments of operation 1425, a surface cleaning process and a plasma activation process are performed on each of the surfaces 1510 and 1514 prior to performing the bonding process. In one or more examples, the pretreatment process can include a wet or dry pre-cleaning type of process, and the plasma activation process can include exposing the surfaces 1510 and 1514 to a plasma that contains a process gas that comprises at least one of He, H₂, N₂, Ar, or O₂. The bonding process can include performing a hybrid bonding process that includes bringing the surfaces 1510 and 1514 into intimate contact, applying a desired amount of force to the multilayer package assembly 1502 and third package assembly 1501C while the multilayer package assembly 1502 and third package assembly 1501C are heated to a bonding temperature that can be between 20° C. and 450° C., such as bonding temperatures between 50° C. and 250° C.

At operation 1430, as shown in FIG. 15C, the third carrier substrate 201C is separated from the device layer stack of the third device layer structure 1507 by breaking the adhesive bond created between the first carrier substrate 201C and the device layer stack by a bonding layer 202 (not shown). The process of separating the third carrier substrate 201C from the device layer stack of the third device layer structure 1507 is used to expose a surface 1540 of the device layer stack of the third device layer structure 1507. The process of separating the third carrier substrate 201C from the device layer stack of the third device layer structure 1507 can be performed by a thermal process, an etching process, or a mechanical separation process. In some cases, it is desirable to remove any residual first bonding layer material from the surface 1540 by use of a wet etch or dry etch cleaning process.

Next, at operation 1435, the surface 1540 is planarized by use of one or more material removal processes to form a substantially planar surface 1545 (FIG. 15D). In some embodiments of operation 1435, the one or more material removal processes include a grinding and/or polishing process, such as a CMP process. The one or more material removal processes are configured to planarize the surface of the device layer stack 120 and remove portions of the electronic devices 116, 117 to expose contacts 116C, 117C of the electronic devices 116, 117. In some embodiments of operation 1435, the contacts 116C and/or 117C are cleaned, dried, and/or a conductive layer is formed thereover after performing the planarization process to assure a desirable contact can be formed in a subsequent processing step.

Next, at operation 1440, as shown in FIG. 15D, an interconnect layer 1528 is formed over the substantially planar surface 1545 to allow at least one of the contacts 116C, 117C to be interconnected to one or more of the other electrical components disposed within the device layer structures 1505, 1506, 1507, electrical components 150, and/or other external electrical components by use of the redistribution layers formed within the interconnect layer 1528. The interconnect layer 1528 can be formed by use of operations 960-985 of method 990 to form the one or more redistribution layers within the interconnect layer 1528. The interconnect layer 1528 can include a plurality of contacts 1520, in which one or more of the contacts 1520 are coupled to a pillar (e.g., pillar 231), a first contact 116C, and a second contact 117C.

### Device Packages and Methods of Forming a Device Package Examples

Embodiments of the disclosure include a method of forming a device package, comprising: forming a device containing layer over a supporting surface of a first substrate, wherein forming the device containing layer comprises: forming a plurality of first openings in a first dielectric layer that is formed over a first conductive layer, wherein the first conductive layer has a first thickness, and is formed over a first bonding layer positioned between the supporting surface and the device containing layer, and a first portion of the first conductive layer is exposed within each of a plurality of first openings formed in the first dielectric layer; forming a second conductive layer on the first portions of the first conductive layer to form a pillar in each of the first openings, wherein the pillars have a second thickness; removing the first dielectric layer, wherein a second portion of the first conductive layer is exposed after removing the first dielectric layer, and the second portion of the first conductive layer is disposed over a first portion of the first substrate; removing the second portion of the first conductive layer; positioning one or more electronic devices over the first portion of the first substrate and adjacent to a pillar, wherein the one or more electronic devices have a device thickness that is less than or equal to the second thickness of the pillar; depositing a molding material over the pillars and the one or more electronic devices; and forming, by use of a material removal process, a planar surface that comprises a portion of the molding material, a portion of the one or more electronic devices, and a portion of the pillars.

In one or more of the embodiments disclosed herein, the one or more electronic devices comprise two or more dies or chiplets, and the two or more dies or chiplets are disposed between at least two pillars.

In one or more of the embodiments disclosed herein, the one or more electronic devices can comprise an electrical contact, and the planar surface further comprises a portion of the electrical contact.

In one or more of the embodiments disclosed herein, the one or more electronic devices comprise an integrated circuit (IC) device or a passive device.

In one or more of the embodiments disclosed herein, the one or more electronic devices have a thickness after forming the planar surface that is less than the device thickness.

In one or more of the embodiments disclosed herein, the first conductive layer and the second conductive layer comprise a metal that is selected from a group consisting of copper (Cu), titanium (Ti), tantalum (Ta), aluminum (Al), cobalt (Co), ruthenium (Ru), molybdenum (Mo), silver (Ag), gold (Au), tungsten (W), and nickel (Ni), and the first thickness is less than the second thickness.

In one or more of the embodiments disclosed above, the method of forming the device package further comprises: depositing a second dielectric layer over the planar surface; forming a plurality of first openings in the second dielectric layer, wherein the portion of one or more electronic devices or the portion of one or more first pillars are positioned within at least one of the plurality of first openings; depositing a third conductive layer over the plurality of first openings in the second dielectric layer and over portions of the second dielectric layer that are disposed between the first openings formed in the second dielectric layer; forming a fourth conductive layer on the third conductive layer; and forming, by use of a material removal process, a planar surface that comprises a portion of the fourth conductive layer and the portions of the second dielectric layer that are disposed between the first openings formed in the second dielectric layer.

In one or more of the embodiments disclosed above, the method of forming the device package further comprises: attaching a second substrate to the formed device containing layer by positioning a second bonding layer between the second substrate and the planar surface of the formed device containing layer; separating the first substrate from the formed device containing layer by breaking a bond formed between the supporting surface of the first substrate and a surface of the formed device containing layer by the first bonding layer, wherein a first surface of the one or more electronic devices is positioned adjacent to the surface of the formed device containing layer; removing material from the surface of the formed device containing layer to form a device containing surface, wherein the device containing surface comprises the first surface of the one or more electronic devices; and forming one or more electrical contacts on an exposed surface of the one or more electronic devices. The method can further comprise: depositing a second dielectric layer over the device containing surface; forming a plurality of first openings in the second dielectric layer, wherein the portion of one or more electronic devices or the portion of one or more first pillars are positioned within at least one of the plurality of first openings; depositing a third conductive layer over the plurality of first openings in the second dielectric layer, wherein a portion of the third conductive layer is formed over portions of the second dielectric layer that are disposed between the first openings formed in the second dielectric layer; forming a fourth conductive layer on the third conductive layer; and forming, by use of a material removal process, a planar surface that comprises a portion of the fourth conductive layer and the portions of the second dielectric layer that are disposed between the first openings formed in the second dielectric layer.

In one or more of the embodiments disclosed herein, a method of forming a device package comprises: forming a plurality of first openings in a dielectric layer that is formed over a first conductive layer, wherein the first conductive layer has a first thickness, the first conductive layer is formed over a surface of a device containing layer that is disposed over a surface of a first substrate, the first conductive layer is formed over a portion of one or more electronic devices and a portion of one or more first pillars disposed within the device containing layer, and the one or more first pillars comprise a second conductive layer, and a first portion of the first conductive layer is exposed within each of a plurality of first openings formed in the dielectric layer; forming a third conductive layer on the first portions of the first conductive layer within each of the plurality of first openings to form a second pillar in each of the first openings, wherein the second pillars have a second thickness; removing the dielectric layer, wherein a second portion of the first conductive layer is exposed after removing the dielectric layer, and the second portion of the first conductive layer is disposed over a first portion of the device containing layer; removing the second portion of the first conductive layer; positioning one or more electronic devices over the first portion of the first substrate and adjacent to a second pillar, wherein the one or more electronic devices have a device thickness that is less than or equal to the second thickness of the second pillar; depositing a molding material over the second pillars and the one or more electronic devices; and forming, by use of a material removal process, a planar surface that comprises a portion of the molding material, a portion of the one or more electronic devices, and a portion of the second pillars. The one or more electronic devices can comprise a plurality of dies or chiplets, and one or more dies of the plurality of dies or one or more of chiplets of the plurality of chiplets are disposed between at least two pillars. The one or more electronic devices can comprise an electrical contact, and the planar surface further comprises a portion of the electrical contact. The one or more electronic devices can comprise an integrated circuit device or a passive device. The one or more electronic devices can have a thickness after forming the planar surface that is less than the device thickness. The first conductive layer and the second conductive layer can comprise a metal that is selected from a group consisting of copper (Cu), titanium (Ti), tantalum (Ta), aluminum (Al), cobalt (Co), ruthenium (Ru), molybdenum (Mo), silver (Ag), gold (Au), tungsten (W), and nickel (Ni), and the first thickness is less than the second thickness.

In one or more of the embodiments disclosed above, the method of forming the device package further comprises: depositing a second dielectric layer over the planar surface; forming a plurality of first openings in the second dielectric layer, wherein the portion of one or more electronic devices or the portion of one or more first pillars are positioned within at least one of the plurality of first openings; depositing a third conductive layer over the plurality of first openings in the second dielectric layer, wherein a portion of the third conductive layer is formed over portions of the second dielectric layer that are disposed between the first openings formed in the second dielectric layer; forming a fourth conductive layer on the third conductive layer; and forming, by use of a material removal process, a planar surface that comprises a portion of the fourth conductive layer and the portions of the second dielectric layer that are disposed between the first openings formed in the second dielectric layer.

In one or more of the embodiments disclosed above, the method of forming the device package further comprises: attaching a second substrate to the formed device containing layer by positioning a second bonding layer between the second substrate and the planar surface of the formed device containing layer; separating the first substrate from the formed device containing layer by breaking a bond formed between a supporting surface of the first substrate and a surface of the formed device containing layer by a first bonding layer, wherein a first surface of the one or more electronic devices is positioned adjacent to the surface of the formed device containing layer; removing material from the surface of the formed device containing layer to form a device containing surface, wherein the device containing surface comprises the first surface of the one or more electronic devices; and forming one or more electrical contacts on an exposed surface of the one or more electronic devices.

In one or more of the embodiments disclosed above, the method of forming the device package further comprises: depositing a second dielectric layer over the device containing surface; forming a plurality of first openings in the second dielectric layer, wherein the portion of one or more electronic devices or the portion of one or more first pillars are positioned within at least one of the plurality of first openings; depositing a third conductive layer over the plurality of first openings in the second dielectric layer, wherein a portion of the third conductive layer is formed over portions of the second dielectric layer that are disposed between the first openings formed in the second dielectric layer; forming a fourth conductive layer on the third conductive layer; and forming, by use of a material removal process, a planar surface that comprises a portion of the fourth conductive layer and the portions of the second dielectric layer that are disposed between the first openings formed in the second dielectric layer.

In one or more of the embodiments disclosed herein, a method of forming a device package comprises: bonding a first device layer structure to a second device layer structure, wherein bonding the first device layer structure to the second device layer structure comprises: bonding conductive regions within an interconnect layer of the first device layer structure to conductive regions within an interconnect layer of the second device layer structure, wherein the first device layer structure is positioned over a first substrate, and the first device layer structure comprises: the interconnect layer, which comprises the conductive regions that are coupled to a plurality of traces, a plurality of pillars that are coupled to the plurality of traces, and a plurality of first electronic devices that comprise device contacts that are coupled to the plurality of traces and the pillars, and the second device layer structure is positioned over a second substrate, and the second device layer structure comprises: the interconnect layer, which comprises the conductive regions that are coupled to a plurality of traces, a plurality of pillars that are coupled to the plurality of traces, and a plurality of second electronic devices that comprise device contacts that are coupled to the plurality of traces and the pillars. The method can further include separating the second substrate from the second device layer structure, wherein separating the second substrate from the second device layer structure exposes a surface of the second device layer structure; and bonding a third device layer structure to the surface of the second device layer structure, wherein bonding the third device layer structure to the second device layer structure comprises: bonding conductive regions within an interconnect layer of the third device layer structure to conductive regions within the interconnect layer of the second device layer structure, wherein the third device layer structure is positioned over a third substrate, and the third device layer structure comprises: the interconnect layer, which comprises the conductive regions that are coupled to a plurality of traces, a plurality of pillars that are coupled to the plurality of traces, and a plurality of third electronic devices that comprise device contacts that are coupled to the plurality of traces and the pillars. The method can further include separating the third substrate from the third device layer structure, wherein separating the third substrate from the third device layer structure exposes a surface of the third device layer structure; and depositing a dielectric layer over the surface of the third device layer structure; forming a plurality of first openings in the dielectric layer, wherein a portion of third electronic devices or a portion of pillars of the third device layer structure are positioned within at least one of the plurality of first openings; depositing a first conductive layer over the plurality of first openings in the dielectric layer, wherein a portion of the first conductive layer is formed over portions of the dielectric layer that are disposed between the first openings formed in the dielectric layer; forming a second conductive layer on the first conductive layer; and forming, by use of a material removal process, a planar surface that comprises a portion of the conductive layer and the portions of the dielectric layer that are disposed between the first openings formed in the dielectric layer.

Embodiments of the disclosure have been described above with reference to specific embodiments and numerous specific details are set forth to provide a more thorough understanding of the present disclosure. Persons skilled in the art, however, will understand that various modifications and changes may be made thereto without departing from the broader spirit and scope of the disclosure. The foregoing description and drawings are, accordingly, to be regarded in an illustrative rather than a restrictive sense.

While the foregoing is directed to embodiments of the present disclosure, other and further embodiments of the disclosure may be devised without departing from the basic scope thereof, and the scope thereof is determined by the claims that follow.

What is claimed is:

1. A method of forming a device package, comprising:
forming a device containing layer over a supporting surface of a first substrate, wherein forming the device containing layer comprises:
forming a plurality of first openings in a first dielectric layer that is formed over a first conductive layer, wherein
the first conductive layer has a first thickness, and is formed over a first bonding layer positioned between the supporting surface and the device containing layer, and
a first portion of the first conductive layer is exposed within each of a plurality of first openings formed in the first dielectric layer;
forming a second conductive layer on the first portions of the first conductive layer to form a pillar in each of the first openings, wherein the pillars have a second thickness;
removing the first dielectric layer, wherein a second portion of the first conductive layer is exposed after removing the first dielectric layer, and the second portion of the first conductive layer is disposed over a first portion of the first substrate;
removing the second portion of the first conductive layer;
positioning one or more electronic devices over the first portion of the first substrate and adjacent to a pillar, wherein the one or more electronic devices have a device thickness that is less than or equal to the second thickness of the pillar;
depositing a molding material over the pillars and the one or more electronic devices; and
forming, by use of a material removal process, a planar surface that comprises a portion of the molding material, a portion of the one or more electronic devices, and a portion of the pillars.

2. The method of claim 1, wherein the one or more electronic devices comprise two or more dies or chiplets, and the two or more dies or chiplets are disposed between at least two pillars.

3. The method of claim 1, wherein the one or more electronic devices comprise an electrical contact, and the planar surface further comprises a portion of the electrical contact.

4. The method of claim 1, wherein the one or more electronic devices comprise an integrated circuit (IC) device or a passive device.

5. The method of claim 1, wherein the one or more electronic devices have a thickness after forming the planar surface that is less than the device thickness.

6. The method of claim 1, wherein the first conductive layer and the second conductive layer comprise a metal that is selected from a group consisting of copper (Cu), titanium (Ti), tantalum (Ta), aluminum (Al), cobalt (Co), ruthenium (Ru), molybdenum (Mo), silver (Ag), gold (Au), tungsten (W), and nickel (Ni), and the first thickness is less than the second thickness.

7. The method of claim 1, further comprising:
depositing a second dielectric layer over the planar surface;
forming a plurality of first openings in the second dielectric layer, wherein the portion of one or more electronic devices or the portion of one or more first pillars are positioned within at least one of the plurality of first openings;
depositing a third conductive layer over the plurality of first openings in the second dielectric layer and over portions of the second dielectric layer that are disposed between the first openings formed in the second dielectric layer;
forming a fourth conductive layer on the third conductive layer; and
forming, by use of a material removal process, a planar surface that comprises a portion of the fourth conductive layer and the portions of the second dielectric layer that are disposed between the first openings formed in the second dielectric layer.

8. The method of claim 1, further comprising:
attaching a second substrate to the formed device containing layer by positioning a second bonding layer between the second substrate and the planar surface of the formed device containing layer;
separating the first substrate from the formed device containing layer by breaking a bond formed between the supporting surface of the first substrate and a surface of the formed device containing layer by the first bonding layer, wherein a first surface of the one or more electronic devices is positioned adjacent to the surface of the formed device containing layer;
removing material from the surface of the formed device containing layer to form a device containing surface, wherein the device containing surface comprises the first surface of the one or more electronic devices; and
forming one or more electrical contacts on an exposed surface of the one or more electronic devices.

9. The method of claim 8, further comprising:
depositing a second dielectric layer over the device containing surface;
forming a plurality of first openings in the second dielectric layer, wherein the portion of one or more electronic devices or the portion of one or more first pillars are positioned within at least one of the plurality of first openings;
depositing a third conductive layer over the plurality of first openings in the second dielectric layer, wherein a portion of the third conductive layer is formed over portions of the second dielectric layer that are disposed between the first openings formed in the second dielectric layer;
forming a fourth conductive layer on the third conductive layer; and
forming, by use of a material removal process, a planar surface that comprises a portion of the fourth conductive layer and the portions of the second dielectric layer that are disposed between the first openings formed in the second dielectric layer.

10. A method of forming a device package, comprising:
forming a plurality of first openings in a dielectric layer that is formed over a first conductive layer, wherein
the first conductive layer has a first thickness,
the first conductive layer is formed over a surface of a device containing layer that is disposed over a surface of a first substrate,
the first conductive layer is formed over a portion of one or more electronic devices and a portion of one or more first pillars disposed within the device containing layer, and the one or more first pillars comprise a second conductive layer, and
a first portion of the first conductive layer is exposed within each of a plurality of first openings formed in the dielectric layer;
forming a third conductive layer on the first portions of the first conductive layer within each of the plurality of first openings to form a second pillar in each of the first openings, wherein the second pillars have a second thickness;
removing the dielectric layer, wherein a second portion of the first conductive layer is exposed after removing the dielectric layer, and the second portion of the first conductive layer is disposed over a first portion of the device containing layer;
removing the second portion of the first conductive layer;
positioning one or more electronic devices over the first portion of the first substrate and adjacent to a second pillar, wherein the one or more electronic devices have a device thickness that is less than or equal to the second thickness of the second pillar;
depositing a molding material over the second pillars and the one or more electronic devices; and
forming, by use of a material removal process, a planar surface that comprises a portion of the molding material, a portion of the one or more electronic devices, and a portion of the second pillars.

11. The method of claim 10, wherein the one or more electronic devices comprise a plurality of dies or chiplets, and one or more dies of the plurality of dies or one or more of chiplets of the plurality of chiplets are disposed between at least two pillars.

12. The method of claim 10, wherein the one or more electronic devices comprise an electrical contact, and the planar surface further comprises a portion of the electrical contact.

13. The method of claim 10, wherein the one or more electronic devices comprise an integrated circuit device or a passive device.

14. The method of claim 10, wherein the one or more electronic devices have a thickness after forming the planar surface that is less than the device thickness.

15. The method of claim 10, wherein the first conductive layer and the second conductive layer comprise a metal that is selected from a group consisting of copper (Cu), titanium (Ti), tantalum (Ta), aluminum (Al), cobalt (Co), ruthenium (Ru), molybdenum (Mo), silver (Ag), gold (Au), tungsten (W), and nickel (Ni), and the first thickness is less than the second thickness.

16. The method of claim 10, further comprising:
depositing a second dielectric layer over the planar surface;
forming a plurality of first openings in the second dielectric layer, wherein the portion of one or more electronic devices or the portion of one or more first pillars are positioned within at least one of the plurality of first openings;
depositing a third conductive layer over the plurality of first openings in the second dielectric layer, wherein a portion of the third conductive layer is formed over portions of the second dielectric layer that are disposed between the first openings formed in the second dielectric layer;
forming a fourth conductive layer on the third conductive layer; and
forming, by use of a material removal process, a planar surface that comprises a portion of the fourth conductive layer and the portions of the second dielectric layer that are disposed between the first openings formed in the second dielectric layer.

17. The method of claim 10, further comprising:
attaching a second substrate to the formed device containing layer by positioning a second bonding layer between the second substrate and the planar surface of the formed device containing layer;
separating the first substrate from the formed device containing layer by breaking a bond formed between a supporting surface of the first substrate and a surface of the formed device containing layer by a first bonding layer, wherein a first surface of the one or more electronic devices is positioned adjacent to the surface of the formed device containing layer;
removing material from the surface of the formed device containing layer to form a device containing surface, wherein the device containing surface comprises the first surface of the one or more electronic devices; and
forming one or more electrical contacts on an exposed surface of the one or more electronic devices.

18. The method of claim 17, further comprising:
depositing a second dielectric layer over the device containing surface;
forming a plurality of first openings in the second dielectric layer, wherein the portion of one or more electronic devices or the portion of one or more first pillars are positioned within at least one of the plurality of first openings;
depositing a third conductive layer over the plurality of first openings in the second dielectric layer, wherein a portion of the third conductive layer is formed over portions of the second dielectric layer that are disposed between the first openings formed in the second dielectric layer;
forming a fourth conductive layer on the third conductive layer; and
forming, by use of a material removal process, a planar surface that comprises a portion of the fourth conductive layer and the portions of the second dielectric layer that are disposed between the first openings formed in the second dielectric layer.

19. A method of forming a device package, comprising:
bonding a first device layer structure to a second device layer structure, wherein bonding the first device layer structure to the second device layer structure comprises:
bonding conductive regions within an interconnect layer of the first device layer structure to conductive regions within an interconnect layer of the second device layer structure, wherein
the first device layer structure is positioned over a first substrate, and the first device layer structure comprises:
the interconnect layer, which comprises the conductive regions that are coupled to a plurality of traces,
a plurality of pillars that are coupled to the plurality of traces, and
a plurality of first electronic devices that comprise device contacts that are coupled to the plurality of traces and the pillars, and
the second device layer structure is positioned over a second substrate, and the second device layer structure comprises:
the interconnect layer, which comprises the conductive regions that are coupled to a plurality of traces,
a plurality of pillars that are coupled to the plurality of traces, and
a plurality of second electronic devices that comprise device contacts that are coupled to the plurality of traces and the pillars; and
separating the second substrate from the second device layer structure, wherein separating the second substrate from the second device layer structure exposes a surface of the second device layer structure; and
bonding a third device layer structure to the surface of the second device layer structure, wherein bonding the third device layer structure to the second device layer structure comprises:
bonding conductive regions within an interconnect layer of the third device layer structure to conductive regions within the interconnect layer of the second device layer structure, wherein
the third device layer structure is positioned over a third substrate, and the third device layer structure comprises:
the interconnect layer, which comprises the conductive regions that are coupled to a plurality of traces,
a plurality of pillars that are coupled to the plurality of traces, and
a plurality of third electronic devices that comprise device contacts that are coupled to the plurality of traces and the pillars.

20. The method of claim 19, further comprising:
separating the third substrate from the third device layer structure, wherein separating the third substrate from the third device layer structure exposes a surface of the third device layer structure;
depositing a dielectric layer over the exposed surface of the third device layer structure;
forming a plurality of first openings in the dielectric layer, wherein a portion of third electronic devices or a portion of pillars of the third device layer structure are positioned within at least one of the plurality of first openings;
depositing a first conductive layer over the plurality of first openings in the dielectric layer, wherein a portion of the first conductive layer is formed over portions of the dielectric layer that are disposed between the first openings formed in the dielectric layer;
forming a second conductive layer on the first conductive layer; and
forming, by use of a material removal process, a planar surface that comprises a portion of the conductive layer and the portions of the dielectric layer that are disposed between the first openings formed in the dielectric layer.
